(19) United States
(12) Patent Application Publication
(10) Pub. No.: US 2026/0109849 A1
(43) Pub. Date: Apr. 23, 2026

(54) EPOXY RESIN COMPOSITION, RESIN PASTE, FILM-TYPE ADHESIVE, PRINTED WIRING BOARD, SEMICONDUCTOR CHIP PACKAGE, AND ELECTRONIC DEVICE

(71) Applicant: ASAHI KASEI KABUSHIKI KAISHA, Tokyo (JP)

(72) Inventors: Naohiro KOBAYASHI, Tokyo (JP); Masanori YOSHIDA, Tokyo (JP)

(73) Assignee: ASAHI KASEI KABUSHIKI KAISHA, Tokyo (JP)

(21) Appl. No.: 19/112,679

(22) PCT Filed: Jun. 13, 2024
(86) PCT No.: PCT/JP2024/021552

§ 371 Date: Mar. 18, 2025

(30) Foreign Application Priority Data
Jul. 3, 2023 (JP) 2023-109093

(51) Int. Cl. C08L 63/00; C08G 59/22; C08G 59/24; C08G 59/42; C08G 59/50; C08G 59/58; C08G 59/62; C08K 3/36; C08K 5/544; C08K 7/18; C09J 7/30; C09J 163/00

(52) U.S. Cl. CPC C08L 63/00; C08G 59/226; C08G 59/245; C08G 59/4223; C08G 59/423; C08G 59/4284; C08G 59/5073; C08G 59/5086; C08G 59/58; C08G 59/621; C08K 3/36; C08K 5/544; C08K 7/18; C09J 7/30; C09J 163/00; C08G 2170/00; C08K 2201/005; C08L 2203/162; C08L 2203/20; C09J 2203/326; C09J 2463/00

(57) ABSTRACT

Epoxy resin composition comprising
component (A): an epoxy resin,
component (B): at least one curing agent selected from the group consisting of a triazine skeleton-containing phenol-based curing agent, an active ester-based curing agent, and a cyanate ester-based curing agent, and
component (C): a compound represented by a predetermined chemical formula, preferably an imidazole compound.

### TECHNICAL FIELD

The present invention relates to an epoxy resin composition, a resin paste, a film-type adhesive, a printed wiring board, a semiconductor chip package, and an electronic device.

### BACKGROUND ART

Epoxy resins have heretofore been utilized for a wide range of purposes such as insulating materials, sealing materials, adhesives, and conductive materials for electric and electronic components including semiconductor devices, matrix resins for fiber-reinforced plastics, and impregnant fixatives for motor coils.

Among others, epoxy resin compositions which are excellent in adhesion and exhibit high reliability are used in adhesives for semiconductor devices or adhesives for printed wiring boards. An epoxy resin, a curing agent such as a phenol resin having reactivity with the epoxy resin, and a curing accelerator which accelerates the reaction of the epoxy resin and the curing agent are generally used as components constituting the epoxy resin compositions.

With recent increase in performance of electronic devices, electronic circuit substrate materials for printed wiring boards and the like employ a buildup layer and are multilayered and required to have finer wiring, a higher density, a lower dielectric dissipation factor for reducing loss of transmission, and reduction in warpage of substrates.

For the packaging of semiconductor chips using the epoxy resin compositions, wafer-level packages or panel-level packages have received attention in order to achieve high productivity or cost reduction. Such packages are also required to have, particularly, reduction in warpage, for applying the epoxy resin compositions to large substrates and curing the epoxy resin compositions.

All of these purposes require in common the epoxy resin compositions to have stability at the time of storage and rapid curability at the time of heating. Furthermore, the epoxy resin compositions are also required to have heat resistance because the quantity of heat generated by electronic devices is increased along with higher densities of electronic components and larger capacities of electronic information to be handled.

As for epoxy resin compositions as insulating resin materials to be applied to wafer-level packages or printed wiring boards, an insulating resin material has heretofore been disclosed which contains a thermosetting resin, an inorganic filler, and a polymer resin having a glass transition temperature of 30° C. or lower, having one or more skeletons selected from a butadiene skeleton, a carbonate skeleton, an acrylic skeleton, and a siloxane skeleton, and further having one or more skeletons selected from an amide skeleton, an imide skeleton, and a urethane skeleton (see, for example, Patent Literature 1). As disclosed therein, the content of the inorganic filler is 80 to 95% by mass with respect to 100% by mass of involatile components of the insulating resin material, the average particle size of the inorganic filler is 5 μm or smaller, and the coefficient of thermal expansion at 25° C. to 150° C. of a cured product of the insulating resin materials is 3 to 30 ppm/° C., whereby the insulating resin material has an effect of high dimensional stability and small warpage.

As for the stability and rapid curability of epoxy resin compositions, a curable composition is disclosed which comprises a curing agent for an anionic curable compound consisting of an imidazole compound having a substituted phenyl group at position 2 of an imidazole ring (see, for example, Patent Literature 2). As disclosed therein, the curable composition can be subjected to selective curing reaction of an epoxy resin in a high-temperature region around 150° C. and is also excellent in preservation stability.

### CITATION LIST

### Patent Literature

Patent Literature 1: Japanese Patent No. 7188486
Patent Literature 2: Japanese Patent Laid-Open No. 2016-29152

### SUMMARY OF INVENTION

### Technical Problem

For reduction in warpage of substrates, approaches have heretofore been performed in which stress responsible for warpage is relaxed by introducing a soft skeleton into a molecule of a resin component such as an epoxy resin or a polymer resin which occupies a large part of an epoxy resin composition; or warpage is suppressed by adding a high concentration of an inorganic filler and thereby allowing a substrate material and an epoxy resin composition to have similar coefficients of linear expansion.

However, as disclosed in Patent Literature 1, an epoxy resin composition, when containing a given amount of a polymer resin having a soft skeleton and having a low glass transition temperature, presents the problem that the epoxy resin composition cannot obtain sufficient heat resistance because the glass transition temperature of its cured product is decreased. Also, an epoxy resin composition, when containing a high concentration of an inorganic filler, presents the problem that the degree of freedom of formulation is limited or that the epoxy resin composition becomes difficult to handle due to elevation in viscosity.

The epoxy resin composition disclosed in Patent Literature 1 presents the problem that the epoxy resin composition is susceptible to improvement in achieving stability at the time of storage and curability at the time of heating.

On the other hand, the epoxy resin composition disclosed in Patent Literature 2 presents the problem that, although stability at the time of storage and curability in a high-temperature region around 150° C. can be achieved as disclosed therein, much remains to be studied on unspecified composition that satisfies all of reduction in warpage and physical properties such as heat resistance and strength, required for purposes such as printed wiring boards or wafer-level packages and panel-level packages.

Accordingly, an object of the present invention is to provide, in light of the problems of the conventional techniques mentioned above, an epoxy resin composition that reduces warpage and can exert even high heat resistance and high strength while achieving stability at the time of storage and curability at the time of heating.

### Solution to Problem

The present inventor has conducted diligent studies and consequently completed the present invention by finding that an epoxy resin composition that reduces warpage and can exert even high heat resistance and high strength while achieving stability at the time of storage and curability at the time of heating can be obtained by adding an imidazole compound having a specific structure as a catalyst to a specific curing agent as an approach totally different from a conventional approach of reducing warpage by adjusting a resin skeleton or the amount of an inorganic filler blended.

Specifically, the present invention is as follows.

[1] An epoxy resin composition comprising
component (A): an epoxy resin,
component (B): at least one curing agent selected from the group consisting of a triazine skeleton-containing phenol-based curing agent, an active ester-based curing agent, and a cyanate ester-based curing agent, and
component (C): a compound represented by the following formula (1) and/or a compound represented by the following formula (2):

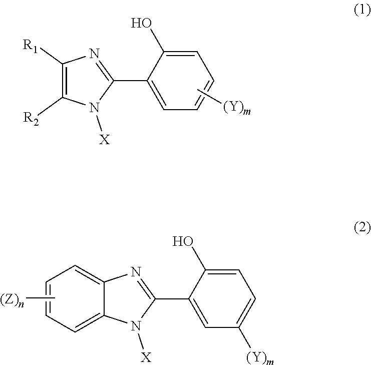

In formulas (1), (2), R₁ and R₂ are each independently any one member selected from the group consisting of a hydrogen atom, a hydroxy group, a carboxy group, a cyano group, a nitro group, a halogen atom, an alkyl group having 1 to 20 carbon atoms and optionally having a substituent, and a cycloalkyl group having 6 to 20 carbon atoms and optionally having a substituent, R₁ and R₂ are the same as or different from each other, and R₁ and R₂ are optionally bonded to each other to form a condensed ring having no aromaticity;
X is any one member selected from the group consisting of a hydrogen atom, an alkyl group having 1 to 20 carbon atoms and optionally having a substituent, an alkenyl group having 2 to 20 carbon atoms and optionally having a substituent, an aralkyl group having 7 to 20 carbon atoms and optionally having a substituent, and a heteroarylalkyl group having 4 to 20 carbon atoms and optionally having a substituent;
each of Y and Z is any one member selected from the group consisting of a hydrogen atom, a halogen atom, a hydroxy group, a carboxy group, a cyano group, a nitro group, an alkyl group having 1 to 20 carbon atoms and optionally having a substituent, an alkoxy group having 1 to 20 carbon atoms and optionally having a substituent, an alkenyl group having 2 to 20 carbon atoms and optionally having a substituent, an aryl group having 6 to 20 carbon atoms and optionally having a substituent, an aryloxy group having 6 to 20 carbon atoms and optionally having a substituent, and an acyl group having 1 to 20 carbon atoms and optionally having a substituent, Y and Z are the same as or different from each other, and two or more Y moieties or two or more Z moieties are optionally bonded to each other to form a monocyclic ring or a condensed ring; and each of m and n is an integer of 1 to 4.

[2] The epoxy resin composition according to [1], further comprising component (D): a filler.

[3] The epoxy resin composition according to [1] or [2], wherein
in the component (C),
each of Y and Z is one member selected from the group consisting of a hydrogen atom, a hydroxy group, a carboxy group, an alkoxy group having 1 to 20 carbon atoms and having no substituent, an alkyl group having 1 to 20 carbon atoms and having a hydroxy group and/or a carboxy group as a substituent, an alkoxy group having 1 to 20 carbon atoms and having a hydroxy group and/or a carboxy group as a substituent, an aryl group having 6 to 20 carbon atoms and having a hydroxy group and/or a carboxy group as a substituent, an aryloxy group having 6 to 20 carbon atoms and having a hydroxy group and/or a carboxy group as a substituent, and an acyl group having 1 to 20 carbon atoms and having a hydroxy group and/or a carboxy group as a substituent.

[4] The epoxy resin composition according to any one of [1] to [3], wherein
in the component (C),
the compound represented by the formula (1) is any member selected from the group consisting of 2-(2-hydroxyphenyl)imidazole, 2-(2-hydroxyphenyl)-4(5)-methylimidazole, 4-ethyl-(2-hydroxyphenyl)-5-methylimidazole, (2-hydroxyphenyl)-4-isopropyl-5-methylimidazole, 4-butyl-(2-hydroxyphenyl)-5-methylimidazole, and 2-(2-hydroxy-3(5)-methoxyphenyl)imidazole,
   and/or
the compound represented by the formula (2) is any member selected from the group consisting of 2-(2-hydroxyphenyl)benzimidazole, 2-(2-hydroxy-3(5)-methoxyphenyl)benzimidazole, 2-(1-hydroxynaphthalen-2-yl)benzimidazole, 2-(2-hydroxynaphthalen-1-yl)benzimidazole, and 2-(2-hydroxyphenyl)benzimidazole-6-carboxylic acid.

[5] The epoxy resin composition according to [4], further comprising component (D): a filler.

[6] A resin paste comprising the epoxy resin composition according to any one of [1] to [5].

[7] A film-type adhesive having
a support, and
a resin layer comprising the epoxy resin composition according to any one of [1] to [5] on the support.

[8] A film-type adhesive having
a support,
a resin layer comprising the epoxy resin composition according to any one of [1] to [5] on the support, and
a protective layer on the resin layer.

[9] A printed wiring board having
a cured product layer of the epoxy resin composition according to any one of [1] to [5].

[10] A semiconductor chip package having
a cured product layer of the epoxy resin composition according to any one of [1] to [5].

[11] An electronic device having the printed wiring board according to [9].

[12] An electronic device having the semiconductor chip package according to [10].

### Advantageous Effect of Invention

The present invention can provide an epoxy resin composition that reduces warpage and can exert even high heat resistance and high strength while achieving stability at the time of storage and curability at the time of heating.

### DESCRIPTION OF EMBODIMENTS

Hereinafter, the mode for carrying out the present invention (hereinafter, referred to as the “present embodiment”) will be described in detail.

The present embodiment described below is given for illustrating the present invention and does not intend to limit the present invention to the contents given below. The present invention can be carried out through appropriate changes or modifications made without departing from the spirit of the present invention.

### [Epoxy Resin Composition]

The epoxy resin composition according to the present embodiment comprises
component (A): an epoxy resin,
component (B): at least one curing agent selected from the group consisting of a triazine skeleton-containing phenol-based curing agent, an active ester-based curing agent, and a cyanate ester-based curing agent, and
component (C): a compound represented by the following formula (1) and/or a compound represented by the following formula (2):

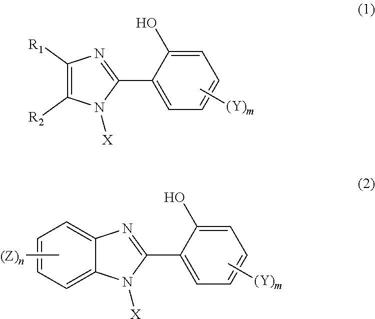

In the formulas (1) and (2),
R₁ and R₂ are each independently any one member selected from the group consisting of a hydrogen atom, a hydroxy group, a carboxy group, a cyano group, a nitro group, a halogen atom, an alkyl group having 1 to 20 carbon atoms and optionally having a substituent, and a cycloalkyl group having 6 to 20 carbon atoms and optionally having a substituent, R₁ and R₂ are the same as or different from each other, and R₁ and R₂ are optionally bonded to each other to form a condensed ring having no aromaticity;
X is any one member selected from the group consisting of a hydrogen atom, an alkyl group having 1 to 20 carbon atoms and optionally having a substituent, an alkenyl group having 2 to 20 carbon atoms and optionally having a substituent, an aralkyl group having 7 to 20 carbon atoms and optionally having a substituent, and a heteroarylalkyl group having 4 to 20 carbon atoms and optionally having a substituent;
each of Y and Z is any one member selected from the group consisting of a hydrogen atom, a halogen atom, a hydroxy group, a carboxy group, a cyano group, a nitro group, an alkyl group having 1 to 20 carbon atoms and optionally having a substituent, an alkoxy group having 1 to 20 carbon atoms and optionally having a substituent, an alkenyl group having 2 to 20 carbon atoms and optionally having a substituent, an aryl group having 6 to 20 carbon atoms and optionally having a substituent, an aryloxy group having 6 to 20 carbon atoms and optionally having a substituent, and an acyl group having 1 to 20 carbon atoms and optionally having a substituent, Y and Z are the same as or different from each other, and two or more Y moieties or two or more Z moieties are optionally bonded to each other to form a monocyclic ring or a condensed ring, and each of m and n is an integer of 1 to 4.

### (Component (A): Epoxy Resin)

The epoxy resin composition of the present embodiment comprises an epoxy resin (hereinafter, also referred to as an epoxy resin (A) or a component (A)).

Examples of the epoxy resin (A) include, but are not limited to, bifunctional epoxy resins such as bisphenol A-type epoxy resin, bisphenol F-type epoxy resin, bisphenol E-type epoxy resin, bisphenol AD-type epoxy resin, bisphenol AF-type epoxy resin, tetrabromobisphenol A-type epoxy resin, biphenyl-type epoxy resin, bixylenol-type epoxy resin, tetrabromobiphenyl-type epoxy resin, diphenyl ether-type epoxy resin, benzophenone-type epoxy resin, phenyl benzoate-type epoxy resin, diphenyl sulfide-type epoxy resin, diphenyl sulfoxide-type epoxy resin, diphenylsulfone-type epoxy resin, diphenyl disulfide-type epoxy resin, naphthalene-type epoxy resin, anthracene-type epoxy resin, hydroquinone-type epoxy resin, methylhydroquinone-type epoxy resin, dibutylhydroquinone-type epoxy resin, resorcinol-type epoxy resin, methylresorcinol-type epoxy resin, catechol-type epoxy resin, and N,N-diglycidyl aniline-type epoxy resin.

Other examples thereof include trifunctional epoxy resins such as N,N-diglycidyl aminobenzene-type epoxy resin, o-(N,N-diglycidyl amino)toluene-type epoxy resin, and triazine-type epoxy resin.

Further examples thereof include tetrafunctional epoxy resins such as naphthalene-type tetrafunctional epoxy resin, tetraglycidyl diaminodiphenylmethane-type epoxy resin, and diaminobenzene-type epoxy resin.

Further examples thereof include polyfunctional epoxy resins such as phenol novolac-type epoxy resin, cresol novolac-type epoxy resin, triphenylmethane-type epoxy resin, tetraphenylethane-type epoxy resin, dicyclopentadiene-type epoxy resin, naphthol aralkyl-type epoxy resin, and brominated phenol novolac-type epoxy resin.

Further examples thereof include diepoxy resins such as (poly)ethylene glycol diglycidyl ether, (poly)propylene glycol diglycidyl ether, butanediol diglycidyl ether, neopentyl glycol diglycidyl ether, 1,6-hexanediol diglycidyl ether, trimethylolpropane diglycidyl ether, polytetramethylene ether glycol diglycidyl ether, glycerin diglycidyl ether, neopentyl glycol diglycidyl ether, cyclohexane-type diglycidyl ether, and dicyclopentadiene-type diglycidyl ether.

Further examples thereof include triepoxy resins such as trimethylolpropane triglycidyl ether and glycerin triglycidyl ether.

Further examples thereof include alicyclic epoxy resins such as vinyl(3,4-cyclohexene) dioxide and 2-(3,4-epoxycyclohexyl)-5,1-spiro-(3,4-epoxycyclohexyl)-m-dioxane.

Further examples thereof include glycidyl amine-type epoxy resins such as tetraglycidyl bis(aminomethyl)cyclohexane.

Further examples thereof include: hydantoin-type epoxy resins such as 1,3-diglycidyl-5-methyl-5-ethylhydantoin; and epoxy resins having a silicone skeleton such as 1,3-bis(3-glycidoxypropyl)-1,1,3,3-tetramethyldisiloxane.

Further examples thereof include aliphatic epoxy resins and alicyclic epoxy resins that can be used as reactive diluents, such as 2-ethyl hexyl glycidyl ether, cyclohexanedimethanol diglycidyl ether, neopentyl glycol diglycidyl ether, 1,6-hexanediol diglycidyl ether, ethylene glycol diglycidyl ether, hydrogenated bisphenol A-type epoxy resin, silicone-modified epoxy resin, (poly)ethylene glycol diglycidyl ether, (poly)propylene glycol diglycidyl ether, butanediol diglycidyl ether, trimethylolpropane diglycidyl ether, polytetramethylene ether glycol diglycidyl ether, glycerin diglycidyl ether, neopentyl glycol diglycidyl ether, cyclohexane-type diglycidyl ether, dicyclopentadiene-type diglycidyl ether, trimethylolpropane triglycidyl ether, glycerin triglycidyl ether, vinyl(3,4-cyclohexene) dioxide, 2-(3,4-epoxycyclohexyl)-5,1-spiro-(3,4-epoxycyclohexyl)-m-dioxane, glycidyl amine-type epoxy resins such as tetraglycidyl bis(aminomethyl)cyclohexane, 1,3-diglycidyl-5-methyl-5-ethylhydantoin-type epoxy resin, 1,3-bis(3-glycidoxypropyl)-1,1,3,3-tetramethyldisiloxane-type epoxy resin, phenyl glycidyl ether, cresyl glycidyl ether, p-s-butyl phenyl glycidyl ether, styrene oxide, p-tert-butyl phenyl glycidyl ether, o-phenyl phenol glycidyl ether, p-phenyl phenol glycidyl ether, N-glycidyl phthalimide, n-butyl glycidyl ether, 2-ethyl hexyl glycidyl ether, α-pinene oxide, allyl glycidyl ether, 1-vinyl-3,4-epoxycyclohexane, 1,2-epoxy-4-(2-methyloxiranyl)-1-methylcyclohexane, 1,3-bis(3-glycidoxypropyl)-1,1,3,3-tetramethyldisiloxane, and neodecanoic acid glycidyl ester.

The epoxy resin (A) may be in a solid or liquid state at ordinary temperature. It is preferred to comprise an epoxy resin that is in a liquid state at ordinary temperature as the epoxy resin (A) because generated stress can be moderately relaxed, thus, in the epoxy resin composition of the present embodiment, warpage tends to be able to be reduced, and moderate tackiness, close contact, and flexibility can be imparted to a film-type adhesive.

Such a liquid epoxy resin is more preferably, but is not limited to, a liquid epoxy resin having a bisphenol A-type structure, a bisphenol F-type structure, a bisphenol AF-type structure, a naphthalene structure, a glycidyl ester structure, a glycidyl amine structure, a phenol novolac structure, a cyclohexane structure, a cyclohexanedimethanol structure, or a butadiene structure, or an alicyclic liquid epoxy resin having an ester skeleton.

Specific examples of the liquid epoxy resin include trade names: EXA850CRP (BisA-type epoxy resin), EXA830CRP (BisF-type epoxy resin), HP4032, HP4032D, and HP4032SS (naphthalene-type epoxy resin) manufactured by DIC Corp., trade names: jER828US, jER828EL, jER825 (bisphenol A-type epoxy resin), jER807, jER1750 (bisphenol F-type epoxy resin), jER152 (phenol novolac-type epoxy resin), jER630, and jER630LSD (glycidyl amine-type epoxy resin) manufactured by Mitsubishi Chemical Group Corp., trade names: ZX1059 (mixed product of bisphenol A-type epoxy resin and bisphenol F-type epoxy resin), “ZX1658”, and “ZX1658GS” (1,4-glycidyl cyclohexane-type liquid epoxy resin) manufactured by NIPPON STEEL Chemical & Material Co., Ltd., trade name: EX-721(glycidyl ester-type epoxy resin) manufactured by Nagase ChemteX Corp., trade names: CELLOXIDE 2021 P (alicyclic epoxy resin having an ester skeleton) and EPOLEAD PB-3600 (epoxy resin having a butadiene structure) manufactured by Daicel Corp., trade name: JP-100, JP-200 (epoxy resin having a butadiene structure) manufactured by Nippon Soda Co., Ltd., and trade name: AER9000 (epoxy resin containing a special soft skeleton) manufactured by Asahi Kasei Corp.

One of these epoxy resins may be used singly, or two or more thereof may be used in combination.

It is preferred to comprise a solid epoxy resin because the epoxy resin (A) can improve the heat resistance of a cured product layer or the strength of a cured product of the epoxy resin composition of the present embodiment.

Examples of such an epoxy resin more preferably include solid epoxy resins having a biphenyl-type structure, a bixylenol structure, a naphthalene structure, a cresol novolac structure, a dicyclopentadiene structure, a trisphenol structure, a naphthol structure, a naphthylene ether structure, an anthracene structure, a bisphenol A-type structure, a bisphenol AF-type structure, a tetraphenylethane structure, a bisphenol acetophenone structure, or a fluorene structure.

Specific examples of the solid epoxy resin include trade names: HP-4700, HP-4710 (naphthalene-type tetrafunctional epoxy resin), N-690, N-695 (cresol novolac-type epoxy resin), HP-7200, HP-7200H, HP-7200HH (dicyclopentadiene-type epoxy resin), HP-6000, HP-6000L, EXA-7311, EXA-7311-G3, EXA-7311-G4, and EXA-7311-G4S (naphthylene ether-type epoxy resin) manufactured by DIC Corp., trade names: EPPN-502H (trisphenol-type epoxy resin), NC3000, NC3000H, NC3000L, NC3100 (biphenyl-type epoxy resin), and NC-7000L (naphthol novolac-type epoxy resin) manufactured by Nippon Kayaku Co., Ltd., trade names: ESN475V and ESN485 (naphthol-type epoxy resin), manufactured by Nippon Steel & Sumikin Chemical Co., Ltd., trade names: YX4000, YX4000H, YX4000HS, YL6121 (biphenyl-type epoxy resin), YX4000HK (bixylenol-type epoxy resin), YX8800 (anthracene-type epoxy resin), YX7700 (novolac-type epoxy resin containing a xylene structure), YL7760 (bisphenol AF-type epoxy resin), YL7800 (fluorene-type epoxy resin), jER1010 (bisphenol A-type solid epoxy resin), and jER1031S (tetraphenylethane-type epoxy resin) manufactured by Mitsubishi Chemical Group Corp., and trade names: OGSOL PG-100 and CG-500 (fluorene-type epoxy resin) manufactured by Osaka Gas Chemicals Co., Ltd.

One of these epoxy resins may be used singly, or two or more thereof may be used in combination.

The liquid epoxy resin and the solid epoxy resin are preferably used in combination as the epoxy resin (A) from the viewpoint of being able to confer the effects mentioned above in a well-balanced manner.

In the case of using the liquid epoxy resin and the solid epoxy resin in combination, their mass ratio (liquid epoxy resin:solid epoxy resin) is not particularly limited and is preferably in the range of 1:0.1 to 1:6.

The mass ratio between the liquid epoxy resin and the solid epoxy resin falls within the above range, whereby effects are obtained, for example, (i) tackiness and close contact are more favorable for use in the form of a film-type adhesive, (ii) sufficient flexibility is obtained for use in the form of a film-type adhesive, and handleability is improved, and (iii) a cured product having sufficient breaking strength can be obtained, and the reliability of a printed wiring board or a semiconductor chip package, and an electronic device comprising the same can be improved.

The mass ratio between the liquid epoxy resin and the solid epoxy resin (liquid epoxy resin: solid epoxy resin) is more preferably in the range of 1:0.3 to 1:5, further preferably in the range of 1:0.6 to 1:4, from the viewpoint of the effects (i) to (iii).

The epoxy resin (A) has an epoxy equivalent of preferably 50 g/eq. to 5000 g/eq., more preferably 50 g/eq. to 3000 g/eq., further preferably 80 g/eq. to 2000 g/eq., still further preferably 100 g/eq. to 1000 g/eq., even further preferably 120 to 900 g/eq.

The epoxy equivalent falls within the above numeric range, whereby a cured product of the epoxy resin composition of the present embodiment has a sufficient cross-link density, and a cured product layer excellent in breaking strength tends to be obtained.

The epoxy equivalent is the mass of a resin containing 1 equivalent of an epoxy group.

The epoxy equivalent can be measured in accordance with JIS K7236.

For the epoxy resin (A), the total chlorine content of the epoxy resin is preferably 2500 ppm or less, more preferably 2000 ppm or less, further preferably 1500 ppm or less, still further preferably 900 ppm or less, from the viewpoint of obtaining an epoxy resin composition excellent in balance between curability and storage stability while having excellent electric characteristics.

The total chlorine content of the epoxy resin (A) is preferably 0.01 ppm or more, more preferably 0.02 ppm or more, further preferably 0.05 ppm or more, still further preferably 0.1 ppm or more, even further preferably 0.2 ppm or more, particularly preferably 0.5 ppm or more, from the viewpoint of suppressing excessive reduction.

In this context, the total chlorine content refers to the total amount of organic chlorine and inorganic chlorine contained in the epoxy resin (A), and is a mass-based value with respect to the epoxy resin (A).

The total chlorine content of the epoxy resin (A) is measured by the following method.

The epoxy resin (A) is repetitively washed and filtered using xylene until the epoxy resin is no longer found in the washing solution xylene. Next, the solvent in the filtrate is distilled off under reduced pressure at 100° C. or lower to obtain an epoxy resin. 1 to 10 g of the obtained epoxy resin sample is precisely weighed such that a titer is 3 to 7 mL. This sample is dissolved in 25 mL of ethylene glycol monobutyl ether. To this solution, 25 mL of a solution of 1 N KOH in propylene glycol is added, and the mixture is boiled for 20 minutes, followed by titration with an aqueous silver nitrate solution. The total chlorine content is calculated from the titer.

The content of the epoxy resin (A) in the epoxy resin composition of the present embodiment can be appropriately set depending on desired performance and is not particularly limited. The content is preferably 5% by mass or more, more preferably 7.5% by mass or more, further preferably 10% by mass or more, still further preferably 12% by mass or more, even further preferably 14% by mass or more, in all involatile components except for a solvent from the viewpoint of curability.

The content is preferably 80% by mass or less, more preferably 70% by mass or less, further preferably 60% by mass or less, still further preferably 55% by mass or less, even further preferably 50% by mass or less, in all involatile components from the viewpoint of the handleability of the epoxy resin composition of the present embodiment and a film-type adhesive comprising the epoxy resin composition of the present embodiment.

### (Component (B): Specific Curing Agent)

The epoxy resin composition of the present embodiment comprises at least one curing agent selected from the group consisting of a triazine skeleton-containing phenol-based curing agent, an active ester-based curing agent, and a cyanate ester-based curing agent (hereinafter, also referred to as a curing agent (B) or a component (B)) as a specific curing agent.

The triazine skeleton-containing phenol-based curing agent functions as a curing agent for epoxy resins and has both of a triazine skeleton and a structure derived from a phenol compound in one molecule. This curing agent is generally produced by the condensation of a phenol compound, a compound having a triazine ring, such as melamine or benzoguanamine, and formaldehyde.

The epoxy resin composition of the present embodiment comprises the triazine skeleton-containing phenol-based curing agent as the component (B), whereby a coefficient of linear expansion can be kept low because of being derived from a triazine skeleton; thus, warpage can be decreased, and heat resistance, strength, and close contact with a base material tend to be favorable.

The nitrogen content of the triazine skeleton-containing phenol-based curing agent is preferably 2% by mass or more, more preferably 4% by mass or more, further preferably 5% by mass or more, still further preferably 6% by mass or more, even further preferably 7% by mass or more, from the viewpoint of more improving the heat resistance, strength, and close contact with a base material of the epoxy resin composition of the present embodiment.

On the other hand, the nitrogen content is preferably 50% by mass or less, more preferably 40% by mass or less, further preferably 30% by mass or less, still further preferably 25% by mass or less, even further preferably 20% by mass or less, from the viewpoint of keeping the stability at the time of storage of the epoxy resin composition of the present embodiment and the cross-link density of a cured product within proper ranges.

The triazine skeleton-containing phenol-based curing agent preferably comprises a phenol novolac structure from the viewpoint of more elevating a cross-link density. Examples of the triazine skeleton-containing phenol-based curing agent comprising a phenol novolac structure include, but are not limited to, trade names: LA3018, LA3018-50P, LA7052, LA7054, and LA1356 manufactured by DIC Corp.

The active ester-based curing agent functions as a curing agent for epoxy resins and has active ester in a molecule.

The epoxy resin composition of the present embodiment comprises the active ester-based curing agent as the component (B), whereby a hydroxy group, which is responsible for increase in dielectric dissipation factor, derived from the reaction of active ester with an epoxy group does not appear in the epoxy resin composition, thus, the dielectric dissipation factor can be decreased.

The active ester-based curing agent is not particularly limited and is preferably a compound having two or more active ester groups in one molecule from the viewpoint of securing a cross-link density. The active ester-based curing agent is more preferably an active ester compound obtained by reacting a carboxylic acid compound and/or a thiocarboxylic acid compound with a hydroxy compound and/or a thiol compound, further preferably an active ester compound obtained by reacting a carboxylic acid compound with one or two or more members selected from a phenol compound, a naphthol compound, and a thiol compound, from the viewpoint of the heat resistance and the like of the epoxy resin composition of the present embodiment. The active ester-based curing agent is still further preferably an aromatic compound having two or more active ester groups in one molecule, the aromatic compound being obtained by reacting a carboxylic acid compound with an aromatic compound having a phenolic hydroxy group. The active ester-based curing agent is even further preferably an aromatic compound obtained by reacting a compound having at least two or more carboxylic acids in one molecule with an aromatic compound having a phenolic hydroxy group, or an aromatic compound having two or more active ester groups in one molecule of the aromatic compound described above.

The active ester-based curing agent may be linear or branched. The compound having at least two or more carboxylic acids in one molecule tends to be able to enhance compatibility with the epoxy resin when being a compound containing an aliphatic chain, and tends to be able to enhance heat resistance when being a compound having an aromatic ring.

In this context, examples of the carboxylic acid compound for use in the preparation of the active ester-based curing agent include benzoic acid, acetic acid, succinic acid, maleic acid, itaconic acid, phthalic acid, isophthalic acid, terephthalic acid, and pyromellitic acid. The carboxylic acid compound is preferably succinic acid, maleic acid, itaconic acid, phthalic acid, isophthalic acid, or terephthalic acid, more preferably isophthalic acid or terephthalic acid, particularly, from the viewpoint of the heat resistance of the epoxy resin composition of the present embodiment.

Examples of the thiocarboxylic acid compound for use in the preparation of the active ester-based curing agent include, but are not particularly limited to, thioacetic acid and thiobenzoic acid.

Examples of the phenol compound or the naphthol compound for use in the preparation of the active ester-based curing agent include, but are not particularly limited to, hydroquinone, resorcinol, bisphenol A, bisphenol F, bisphenol S, phenolphthalein, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucinol, benzenetriol, dicyclopentadienyl diphenol, and phenol novolac. Among them, the phenol or naphthol compound is preferably bisphenol A, bisphenol F, bisphenol S, methylated bisphenol A, methylated bisphenol F, methylated bisphenol S, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucinol, benzenetriol, dicyclopentadienyl diphenol, or phenol novolac, more preferably catechol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucinol, benzenetriol, dicyclopentadienyl diphenol, or phenol novolac, further preferably 1,5-dihydroxynaphthalene, 1,6-dihydroxynaphthalene, 2,6-dihydroxynaphthalene, dihydroxybenzophenone, trihydroxybenzophenone, tetrahydroxybenzophenone, dicyclopentadienyl diphenol, or phenol novolac, still further preferably dihydroxybenzophenone, trihydroxybenzophenone, tetrahydroxybenzophenone, dicyclopentadienyl diphenol, or phenol novolac, even further preferably dicyclopentadienyl diphenol or phenol novolac, particularly preferably dicyclopentadienyl diphenol, from the viewpoint of the heat resistance of the epoxy resin composition of the present embodiment and solubility in the epoxy resin or a solvent.

Examples of the thiol compound for use in the preparation of the active ester-based curing agent include, but are not particularly limited to, benzenedithiol and triazinedithiol.

An active ester compound disclosed in Japanese Patent Laid-Open No. 2004-277460 or 2013-40270 may be used as the active ester compound serving as the active ester-based curing agent, and a commercially available active ester compound can also be used. Examples of the commercially available active ester compound include trade names: EXB9451, EXB9460, EXB9460S, HPC-8000-65T (active ester compound having a dicyclopentadiene-type diphenol structure), EXB9416-70BK (active ester compound having a naphthalene structure), and EXB9050L-62M (phosphorus atom-containing active ester compound) manufactured by DIC Corp., and trade names: DC808 (active ester compound containing an acetylated product of phenol novolac) and YLH1026 (active ester compound containing a benzoylated product of phenol novolac) manufactured by Mitsubishi Chemical Group Corp.

The cyanate ester-based curing agent functions as a curing agent for epoxy resins and has a cyanate group in a molecule. The epoxy resin composition of the present embodiment comprises the cyanate ester-based curing agent as the component (B), whereby flexibility is imparted to the epoxy resin composition by forming an oxazoline ring or an oxazolidinone ring through reaction with an epoxy group, while triazine skeleton formation occurs by the trimerization of a cyanate group; thus, heat resistance tends to be able to be favorable with warpage reduced. Furthermore, a hydroxy group is unlikely to appear during reaction; thus, a dielectric dissipation factor tends to be able to be kept low.

Examples of the cyanate ester-based curing agent include, but are not limited to, novolac-type (phenol novolac-type, alkylphenol novolac-type, etc.) cyanate ester resin, dicyclopentadiene-type cyanate ester resin, bisphenol-type (bisphenol A-type, bisphenol F-type, bisphenol S-type, etc.) cyanate ester resin, and prepolymers obtained by partially converting these resins to triazine. Specific examples of the cyanate ester resin include bifunctional cyanate resins such as bisphenol A dicyanate, polyphenol cyanate (oligo(3-methylene-1,5-phenylene cyanate), 4,4′-methylenebis(2,6-dimethylphenyl cyanate), 4,4′-ethylidene diphenyl dicyanate, hexafluorobisphenol A dicyanate, 2,2-bis(4-cyanato)phenylpropane, 1,1-bis(4-cyanatophenylmethane), bis(4-cyanato-3,5-dimethylphenyl)methane, 1,3-bis(4-cyanatophenyl-1-(methylethylidene))benzene, and bis(4-cyanatophenyl)thio ether, bis(4-cyanatophenyl) ether, polyfunctional cyanate resins such as phenol novolac, cresol novolac, and dicyclopentadiene structure-containing phenol resin, and prepolymers obtained by partially converting these cyanate resins to triazine.

One of these resins may be used, or two or more thereof may be used in combination.

Examples of the commercially available cyanate ester resin include trade name: CYTESTER® TA (bisphenol A-type cyanate ester resin) manufactured by Mitsubishi Gas Chemical Co., Inc.

One of the triazine skeleton-containing phenol-based curing agent, the active ester-based curing agent, and the cyanate ester-based curing agent mentioned above may be used singly. Two or more thereof are preferably combined, and the active ester-based curing agent and the triazine skeleton-containing phenol-based curing agent, or the cyanate ester-based curing agent and the triazine skeleton-containing phenol-based curing agent are more preferably combined, from the viewpoint of securing close contact and adhesion while keeping a dielectric dissipation factor and warpage small for the epoxy resin composition of the present embodiment.

The mass ratio between the curing agents in combining two components (B) as mentioned above is not particularly limited and can be properly set depending on desired physical properties by those skilled in the art. For example, in the case of combining the active ester-based curing agent and the triazine skeleton-containing phenol-based curing agent, the mass ratio of involatile components except for a solvent with the active ester-based curing agent defined as 1 is preferably (active ester-based curing agent:triazine skeleton-containing phenol-based curing agent)=1:0.05 to 1:1.5, more preferably 1:0.05 to 1:1, further preferably 1:0.07 to 1:0.8, still further preferably 1:0.1 to 1:0.6, from the viewpoint of favorably achieving close contact and adhesion while keeping a dielectric dissipation factor and warpage small for the epoxy resin composition of the present embodiment.

For example, in the case of combining the cyanate ester-based curing agent and the triazine skeleton-containing phenol-based curing agent, the mass ratio of involatile components except for a solvent with the cyanate ester-based curing agent defined as 1 is preferably (cyanate ester-based curing agent:triazine skeleton-containing phenol-based curing agent)=1:0.05 to 1:2.0, more preferably 1:0.1 to 1:1.5, further preferably 1:0.2 to 1:1.2, still further preferably 1:0.3 to 1:1, from the same viewpoint as above.

The content of the component (B) in the epoxy resin composition of the present embodiment can be appropriately set depending on desired performance and is not particularly limited. When the number of epoxy groups in the epoxy resin (A) is 1, the number of reactive groups in the component (B) is preferably 0.1 to 3, more preferably 0.15 to 2.5, further preferably 0.2 to 2, still further preferably 0.3 to 1.8, even further preferably 0.35 to 1.5, particularly preferably 0.5 to 1.2, from the viewpoint of adjusting the cross-link density of the component (A) and the component (B) to a proper range and preventing an unreacted functional group from remaining.

In this context, the “number of epoxy groups” is a value obtained by dividing the mass of each epoxy resin present in the epoxy resin composition by an epoxy equivalent and adding up the resulting values as to all epoxy resins. The “reactive group” means a functional group that can react with an epoxy group, and the “number of reactive groups” is a value obtained by dividing the mass of an involatile component by a reactive group equivalent as to each of the triazine skeleton-containing phenol-based curing agent, the active ester-based curing agent, and the cyanate ester-based curing agent present in the epoxy resin composition and adding up all the resulting values.

### (Component (C): Compound Represented by Formula (1) or (2) Given Below)

The epoxy resin composition of the present embodiment comprises a compound represented by the following formula (1) and/or a compound represented by the following formula (2) (hereinafter, also referred to as a compound (C) or a component (C)).

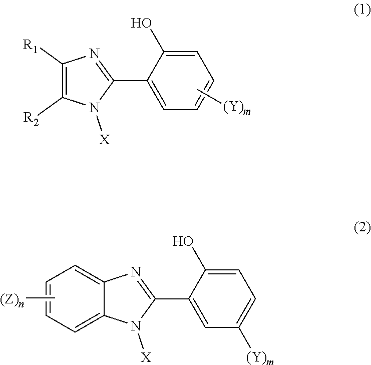

In the formulas (1) and (2), R₁ and R₂ are each independently any one member selected from the group consisting of a hydrogen atom, a hydroxy group, a carboxy group, a cyano group, a nitro group, a halogen atom, an alkyl group having 1 to 20 carbon atoms and optionally having a substituent, and a cycloalkyl group having 6 to 20 carbon atoms and optionally having a substituent, R₁ and R₂ are the same as or different from each other, and R₁ and R₂ are optionally bonded to each other to form a condensed ring having no aromaticity.

X is any one member selected from the group consisting of a hydrogen atom, an alkyl group having 1 to 20 carbon atoms and optionally having a substituent, an alkenyl group having 2 to 20 carbon atoms and optionally having a substituent, an aralkyl group having 7 to 20 carbon atoms and optionally having a substituent, and a heteroarylalkyl group having 4 to 20 carbon atoms and optionally having a substituent.

Each of Y and Z is any one member selected from the group consisting of a hydrogen atom, a halogen atom, a hydroxy group, a carboxy group, a cyano group, a nitro group, an alkyl group having 1 to 20 carbon atoms and optionally having a substituent, an alkoxy group having 1 to 20 carbon atoms and optionally having a substituent, an alkenyl group having 2 to 20 carbon atoms and optionally having a substituent, an aryl group having 6 to 20 carbon atoms and optionally having a substituent, an aryloxy group having 6 to 20 carbon atoms and optionally having a substituent, and an acyl group having 1 to 20 carbon atoms and optionally having a substituent, Y and Z are the same as or different from each other, and two or more Y moieties or two or more Z moieties are optionally bonded to each other to form a monocyclic ring or a condensed ring.

Each of m and n is an integer of 1 to 4.

R₁ and R₂ in the general formula (1) are, as mentioned above, each independently one member selected from the group consisting of a hydrogen atom, a hydroxy group, a carboxy group, a cyano group, a nitro group, a halogen atom, an alkyl group having 1 to 20 carbon atoms and optionally having a substituent, and a cycloalkyl group having 6 to 20 carbon atoms and optionally having a substituent, or R₁ and R₂ have a structure on the same condensed ring having no aromaticity, and R₁ and R₂ are the same as or different from each other.

The alkyl group having 1 to 20 carbon atoms may be linear or branched, and the number of carbon atoms in the alkyl group is preferably 1 to 18, more preferably 1 to 15, further preferably 1 to 10. Examples of the alkyl group having 1 to 20 carbon atoms include a methyl group, an ethyl group, an isopropyl group, a butyl group, an isobutyl group, a hexyl group, an octyl group, and a 2-ethylhexyl group.

The number of carbon atoms in the cycloalkyl group having 6 to 20 carbon atoms is preferably 6 to 18, more preferably 6 to 15. Examples of the cycloalkyl group having 6 to 20 carbon atoms include a cyclohexyl group, a cycloheptane group, and a cyclooctane group.

Specific examples of the structure of R₁ and R₂ on the same condensed ring having no aromaticity include cyclopentane, cyclohexane, and dicyclopentadiene.

The alkyl group, the cycloalkyl group, and the structure of R₁ and R₂ on the same condensed ring having no aromaticity may each have a substituent. Examples of the substituent include a halogen atom, a hydroxy group, an alkoxy group, and a nitro group. The substituent is preferably a hydroxy group or an alkoxy group.

X in the formulas (1) and (2) is any one member selected from the group consisting of a hydrogen atom, an alkyl group having 1 to 20 carbon atoms and optionally having a substituent, an alkenyl group having 2 to 20 carbon atoms and optionally having a substituent, an aralkyl group having 7 to 20 carbon atoms and optionally having a substituent, and a heteroarylalkyl group having 4 to 20 carbon atoms and optionally having a substituent.

The alkyl group having 1 to 20 carbon atoms as X may be linear or branched, and the number of carbon atoms in the alkyl group is preferably 1 to 18, more preferably 1 to 15. Examples of the alkyl group having 1 to 20 carbon atoms include a methyl group, an ethyl group, an isopropyl group, a butyl group, an isobutyl group, a hexyl group, and an octyl group.

The alkenyl group having 2 to 20 carbon atoms as X may be linear or branched, and the number of carbon atoms in the alkenyl group is preferably 2 to 18, more preferably 2 to 15. Examples of the alkenyl group having 2 to 20 carbon atoms include a vinyl group, an aryl group, a 1-propenyl group, an isopropenyl group, a 2-butenyl group, a 3-butenyl group, a 2-pentenyl group, and a 2-hexenyl group.

The aralkyl group having 7 to 20 carbon atoms as X may be linear or branched, and the number of carbon atoms in the aralkyl group is preferably 7 to 18, more preferably 7 to 15. Examples of the aralkyl group having 7 to 20 carbon atoms include a benzyl group, a phenethyl group, and a naphthylmethyl group.

The heteroarylalkyl group having 4 to 20 carbon atoms as X may be linear or branched, and the number of carbon atoms in the heteroarylalkyl group is preferably 4 to 18, more preferably 4 to 15. Examples of the heteroarylalkyl group having 4 to 20 carbon atoms include a triazinylmethyl group, a triazinylethyl group, a 2-pyridylmethyl group, a 2-pyridylethyl group, a 3-pyridylmethyl group, a 3-pyridylethyl group, a 4-pyridylmethyl group, and a 4-pyridylethyl group.

The alkyl group, the alkenyl group, the aralkyl group, and the heteroarylalkyl group may each have a substituent. Examples of the substituent include a halogen atom, a cyano group, a nitro group, a hydroxy group, an alkoxy group, an amino group, an ester group, an arylsulfonyl group, an alkylsulfonyl group, and a phenyl group. The substituent is preferably a cyano group, an alkoxy group, an amino group, an ester group, or a phenyl group.

Each of Y and Z in the general formulas (1) and (2) is any one member selected from the group consisting of a hydrogen atom, a halogen atom, a hydroxy group, a carboxy group, a cyano group, a nitro group, an alkyl group having 1 to 20 carbon atoms and optionally having a substituent, an alkoxy group having 1 to 20 carbon atoms and optionally having a substituent, an alkenyl group having 2 to 20 carbon atoms and optionally having a substituent, an aryl group having 6 to 20 carbon atoms and optionally having a substituent, an aryloxy group having 6 to 20 carbon atoms and optionally having a substituent, and an acyl group having 1 to 20 carbon atoms and optionally having a substituent, or has a structure where two or more Y moieties or two or more Z moieties are bonded to each other to form a monocyclic ring or a condensed ring, and each of m and n is an integer of 1 to 4.

The alkyl group having 1 to 20 carbon atoms as Y or Z may be linear or branched, and the number of carbon atoms in the alkyl group is preferably 1 to 18, more preferably 1 to 15. Examples of the alkyl group having 1 to 20 carbon atoms include a methyl group, an ethyl group, a propyl group, an isopropyl group, a butyl group, an isobutyl group, a hexyl group, an octyl group, a 2-ethylhexyl group, a decyl group, and an undecyl group.

The alkoxy group having 1 to 20 carbon atoms as Y or Z may be linear or branched, and the number of carbon atoms is preferably 1 to 18, more preferably 1 to 15. Examples of the alkoxy group having 1 to 20 carbon atoms include a methoxy group, an ethoxy group, a propoxy group, an isopropoxy group, a butoxy group, a hexyloxy group, and a 2-ethylhexyloxy group.

The alkenyl group having 2 to 20 carbon atoms as Y or Z may be linear or branched, and the number of carbon atoms in the alkenyl group is preferably 2 to 18, more preferably 2 to 15. Examples of the alkenyl group having 2 to 20 carbon atoms include a vinyl group, an aryl group, a 1-propenyl group, an isopropenyl group, a 2-butenyl group, a 3-butenyl group, a 2-pentenyl group, and a 2-hexenyl group.

The number of carbon atoms in the aryl group having 6 to 20 carbon atoms as Y or Z is preferably 6 to 18, more preferably 6 to 15. Examples of the aryl group having 6 to 20 carbon atoms include a phenyl group, a naphthyl group, an anthracenyl group, and a biphenyl group.

Examples of the structure where two or more Y moieties or two or more Z moieties are bonded to each other to form a monocyclic ring or a condensed ring include a naphthyl group and an anthracenyl group.

The number of carbon atoms in the acyl group having 1 to 20 carbon atoms as Y or Z is preferably 1 to 18, more preferably 1 to 15. Examples of the acyl group having 1 to 20 carbon atoms include an acetyl group, a benzoyl group, and a pivaloyl group.

The alkyl group, the alkoxy group, the alkenyl group, the aryl group, the aryloxy group, and the acyl group may each have a substituent. Examples of the substituent include an alkyl group, a halogen atom, a hydroxy group, a carboxy group, an alkoxy group, a nitro group, an ester group, and a phenyl group. The substituent is preferably an alkyl group, a hydroxy group, a carboxy group, or an alkoxy group.

Y may be substituted at any of the ortho, meta, and para positions of the substituent phenyl group at position 2 of imidazole and, in the case of having a substituent, is preferably substituted at a position other than the ortho position, preferably substituted at least at the meta position, and more preferably substituted at the meta position by a hydroxy group or an alkoxy group having 1 to 20 carbon atoms and optionally having a substituent.

Among those described above, each of Y and Z in the general formulas (1) and (2) is more preferably any member selected from the group consisting of a hydrogen atom, a hydroxy group, a carboxy group, an alkoxy group having 1 to 20 carbon atoms and having no substituent, an alkyl group having 1 to 20 carbon atoms and having a hydroxy group and/or a carboxy group as a substituent, an alkoxy group having 1 to 20 carbon atoms and having a hydroxy group and/or a carboxy group as a substituent, an aryl group having 6 to 20 carbon atoms and having a hydroxy group and/or a carboxy group as a substituent, an aryloxy group having 6 to 20 carbon atoms and having a hydroxy group and/or a carboxy group as a substituent, an acyl group having 1 to 20 carbon atoms and having a hydroxy group and/or a carboxy group as a substituent.

Each of Y and Z is a hydrogen atom, whereby a cured product obtained using the epoxy resin composition of the present embodiment can have a lower dielectric dissipation factor.

When each of Y and Z is a hydroxy group, a carboxy group, an alkoxy group having 1 to 20 carbon atoms and having no substituent, an alkyl group having 1 to 20 carbon atoms and having a hydroxy group and/or a carboxy group as a substituent, an alkoxy group having 1 to 20 carbon atoms and having a hydroxy group and/or a carboxy group as a substituent, an aryl group having 6 to 20 carbon atoms and having a hydroxy group and/or a carboxy group as a substituent, an aryloxy group having 6 to 20 carbon atoms and having a hydroxy group and/or a carboxy group as a substituent, or an acyl group having 1 to 20 carbon atoms and having a hydroxy group and/or a carboxy group as a substituent, coordination bondability to an adherend such as a metal is increased: thus, close contact and adhesion strength tend to be able to be improved.

Examples of the compound represented by the general formula (1) include, but are not limited to, the following imidazole compounds:

2-(2-hydroxyphenyl)imidazole, 2-(2-hydroxyphenyl)-4(5)-methylimidazole, 4(5)-ethyl-2-(2-hydroxyphenyl)imidazole, 4,5-dimethyl-2-(2-hydroxyphenyl)imidazole, 4-ethyl-(2-hydroxyphenyl)-5-methylimidazole, (2-hydroxyphenyl)-4-isopropyl-5-methylimidazole, 4-butyl-(2-hydroxyphenyl)-5-methylimidazole, 2-(2-hydroxy-3-methylphenyl)imidazole, 2-(2-hydroxy-3-methylphenyl)-4(5)-methylimidazole, 4(5)-ethyl-2-(2-hydroxy-3-methylphenyl)imidazole, 4,5-dimethyl-2-(2-hydroxy-3-methylphenyl)imidazole, 4-ethyl-(2-hydroxy-3-methylphenyl)-5-methylimidazole, (2-hydroxy-3-methylphenyl)-4-isopropyl-5-methylimidazole, 4-butyl-(2-hydroxy-3-methylphenyl)-5-methylimidazole, 2-(2-hydroxy-4-methylphenyl)imidazole, 2-(2-hydroxy-4-methylphenyl)-4(5)-methylimidazole, and 4(5)-ethyl-2-(2-hydroxy-4-methylphenyl)imidazole.

Other examples thereof include 4,5-dimethyl-2-(2-hydroxy-4-methylphenyl)imidazole, 4-ethyl-(2-hydroxy-4-methylphenyl)-5-methylimidazole, (2-hydroxy-4-methylphenyl)-4-isopropyl-5-methylimidazole, 4-butyl-(2-hydroxy-4-methylphenyl)-5-methylimidazole, 2-(2-hydroxy-5-methylphenyl)imidazole, 2-(2-hydroxy-5-methylphenyl)-4(5)-methylimidazole, 4(5)-ethyl-2-(2-hydroxy-5-methylphenyl)imidazole, 4,5-dimethyl-2-(2-hydroxy-5-methylphenyl)imidazole, 4-ethyl-(2-hydroxy-5-methylphenyl)-5-methylimidazole, (2-hydroxy-5-methylphenyl)-4-isopropyl-5-methylimidazole, 4-butyl-(2-hydroxy-5-methylphenyl)-5-methylimidazole, 2-(3-t-butyl-2-hydroxyphenyl)imidazole, 2-(3-t-butyl-2-hydroxyphenyl)-4(5)-methylimidazole, and 2-(3-t-butyl-2-hydroxyphenyl)-4(5)-ethylimidazole.

Further examples thereof include 2-(3-t-butyl-2-hydroxyphenyl)-4,5-dimethylimidazole, 2-(3-t-butyl-2-hydroxyphenyl)-4-ethyl-5-methylimidazole, 2-(3-t-butyl-2-hydroxyphenyl)-4-isopropyl-5-methylimidazole, 4-butyl-2-(3-t-butyl-2-hydroxyphenyl)-5-methylimidazole, 2-(4-fluoro-2-hydroxyphenyl)imidazole, 2-(4-fluoro-2-hydroxyphenyl)-4(5)-methylimidazole, 2-(4-fluoro-2-hydroxyphenyl)-4(5)-ethylimidazole, 2-(4-fluoro-2-hydroxyphenyl)-4,5-dimethylimidazole, 4-ethyl-2-(4-fluoro-2-hydroxyphenyl)-5-methylimidazole, 2-(4-fluoro-2-hydroxyphenyl)-4-isopropyl-5-methylimidazole, 4-butyl-2-(4-fluoro-2-hydroxyphenyl)-5-methylimidazole, 2-(4-chloro-2-hydroxyphenyl)imidazole, 2-(4-chloro-2-hydroxyphenyl)-4(5)-methylimidazole, and 2-(4-chloro-2-hydroxyphenyl)-4(5)-ethylimidazole.

Further examples thereof include 2-(4-chloro-2-hydroxyphenyl)-4,5-dimethylimidazole, 2-(4-chloro-2-hydroxyphenyl)-4-ethyl-5-methylimidazole, 2-(4-chloro-2-hydroxyphenyl)-4-isopropyl-5-methylimidazole, 4-butyl-2-(4-chloro-2-hydroxyphenyl)-5-methylimidazole, 2-(4-bromo-2-hydroxyphenyl)imidazole, 2-(4-bromo-2-hydroxyphenyl)-4(5)-methylimidazole, 2-(4-bromo-2-hydroxyphenyl)-4(5)-ethylimidazole, 2-(4-bromo-2-hydroxyphenyl)-4,5-dimethylimidazole, 2-(4-bromo-2-hydroxyphenyl)-4-ethyl-5-methylimidazole, 2-(4-bromo-2-hydroxyphenyl)-4-isopropyl-5-methylimidazole, 2-(4-bromo-2-hydroxyphenyl)-4-butyl-5-methylimidazole, and 2-(2,3-dihydroxyphenyl)imidazole.

Further examples thereof include 2-(2,3-dihydroxyphenyl)-4(5)-methylimidazole, 2-(2,3-dihydroxyphenyl)-4(5)-ethylimidazole, 2-(2,3-dihydroxyphenyl)-4,5-dimethylimidazole, 2-(2,3-dihydroxyphenyl)-4(5)-phenylimidazole, 2-(2,3-dihydroxyphenyl)-4,5-diphenylimidazole, 2-(2,5-dihydroxyphenyl)imidazole, 2-(2,5-dihydroxyphenyl)-4(5)-methylimidazole, 2-(2,5-dihydroxyphenyl)-4(5)-ethylimidazole, 2-(2,5-dihydroxyphenyl)-4,5-dimethylimidazole, 2-(2,5-dihydroxyphenyl)-4(5)-phenylimidazole, 2-(2,5-dihydroxyphenyl)-4,5-diphenylimidazole, 2-(2-hydroxy-4-methoxyphenyl)imidazole, 2-(2-hydroxy-4-methoxyphenyl)-4(5)-methylimidazole, 4(5)-ethyl-2-(2-hydroxy-4-methoxyphenyl)imidazole, 4,5-dimethyl-2-(2-hydroxy-4-methoxyphenyl)imidazole, 2-(2-hydroxy-4-methoxyphenyl)-4(5)-phenylimidazole, 4,5-diphenyl-2-(2-hydroxy-4-methoxyphenyl)imidazole, 2-(2-hydroxy-3-methoxyphenyl)imidazole, 2-(2-hydroxy-3-methoxyphenyl)-4(5)-methylimidazole, and 4(5)-ethyl-2-(2-hydroxy-3-methoxyphenyl)imidazole.

Further examples thereof include 4,5-dimethyl-2-(2-hydroxy-3-methoxyphenyl)imidazole, 2-(2-hydroxy-3-methoxyphenyl)-4(5)-phenylimidazole, 4,5-diphenyl-2-(2-hydroxy-3-methoxyphenyl)imidazole, 2-(2-hydroxy-5-methoxyphenyl)imidazole, 2-(2-hydroxy-5-methoxyphenyl)-4(5)-methylimidazole, 4(5)-ethyl-2-(2-hydroxy-5-methoxyphenyl)imidazole, 4,5-dimethyl-2-(2-hydroxy-5-methoxyphenyl)imidazole, 2-(2-hydroxy-5-methoxyphenyl)-4(5)-phenylimidazole, 4,5-diphenyl-2-(2-hydroxy-5-methoxyphenyl)imidazole, 2-(2-hydroxy-6-methoxyphenyl)imidazole, 2-(2-hydroxy-6-methoxyphenyl)-4(5)-methylimidazole, 4(5)-ethyl-2-(2-hydroxy-6-methoxyphenyl)imidazole, 4,5-dimethyl-2-(2-hydroxy-6-methoxyphenyl)imidazole, 2-(2-hydroxy-6-methoxyphenyl)-4(5)-phenylimidazole, 4,5-diphenyl-2-(2-hydroxy-6-methoxyphenyl)imidazole, 2-(3-ethoxy-2-hydroxyphenyl)imidazole, 2-(3-ethoxy-2-hydroxyphenyl)-4(5)-methylimidazole, 2-(3-ethoxy-2-hydroxyphenyl)-4(5)-ethylimidazole, 4,5-dimethyl-2-(3-ethoxy-2-hydroxyphenyl)imidazole, and 2-(3-ethoxy-2-hydroxyphenyl)-4(5)-phenylimidazole.

Further examples thereof include 4,5-diphenyl-2-(3-ethoxy-2-hydroxyphenyl)imidazole, 2-(5-ethoxy-2-hydroxyphenyl)imidazole, 2-(5-ethoxy-2-hydroxyphenyl)-4(5)-methylimidazole, 2-(5-ethoxy-2-hydroxyphenyl)-4(5)-ethylimidazole, 4,5-dimethyl-2-(5-ethoxy-2-hydroxyphenyl)imidazole, 2-(5-ethoxy-2-hydroxyphenyl)-4(5)-phenylimidazole, 4,5-diphenyl-2-(5-ethoxy-2-hydroxyphenyl)imidazole, 2-(4-allyl-2-hydroxy-3-methoxyphenyl)imidazole, 2-(4-allyl-2-hydroxy-3-methoxyphenyl)-4(5)-methylimidazole, 2-(4-allyl-2-hydroxy-3-methoxyphenyl)-4(5)-ethylimidazole, 2-(4-allyl-2-hydroxy-3-methoxyphenyl)-4,5-dimethylimidazole, 2-(4-allyl-2-hydroxy-3-methoxyphenyl)-4(5)-phenylimidazole, 2-(4-allyl-2-hydroxy-3-methoxyphenyl)-4,5-diphenylimidazole, and 2-(4,6-dimethoxy-2-hydroxyphenyl)imidazole.

Further examples thereof include 2-(4,6-dimethoxy-2-hydroxyphenyl)-4(5)-methylimidazole, 2-(4,6-dimethoxy-2-hydroxyphenyl)-4(5)-ethylimidazole, 2-(4,6-dimethoxy-2-hydroxyphenyl)-4,5-dimethylimidazole, 2-(4,6-dimethoxy-2-hydroxyphenyl)-4(5)-phenylimidazole, 2-(4,6-dimethoxy-2-hydroxyphenyl)-4,5-diphenylimidazole, 2-(2-fluoro-5-hydroxyphenyl)imidazole, 2-(2-fluoro-5-hydroxyphenyl)-4(5)-methylimidazole, 2-(2-fluoro-5-hydroxyphenyl)-4(5)-ethylimidazole, 2-(2-fluoro-5-hydroxyphenyl)-4,5-dimethylimidazole, 2-(2-fluoro-5-hydroxyphenyl)-4(5)-phenylimidazole, 2-(2-fluoro-5-hydroxyphenyl)-4,5-diphenylimidazole, 2-(5-fluoro-2-hydroxyphenyl)imidazole, 2-(5-fluoro-2-hydroxyphenyl)-4(5)-methylimidazole, and 2-(5-fluoro-2-hydroxyphenyl)-4(5)-ethylimidazole.

Further examples thereof include 2-(5-fluoro-2-hydroxyphenyl)-4,5-dimethylimidazole, 2-(5-fluoro-2-hydroxyphenyl)-4(5)-phenylimidazole, 2-(5-fluoro-2-hydroxyphenyl)-4,5-diphenylimidazole, 2-(5-chloro-2-hydroxyphenyl)imidazole, 2-(5-chloro-2-hydroxyphenyl)-4(5)-methylimidazole, 2-(5-chloro-2-hydroxyphenyl)-4(5)-ethylimidazole, 2-(5-chloro-2-hydroxyphenyl)-4,5-dimethylimidazole, 2-(5-chloro-2-hydroxyphenyl)-4(5)-phenylimidazole, 2-(5-chloro-2-hydroxyphenyl)-4,5-diphenylimidazole, 2-(5-bromo-2-hydroxyphenyl)imidazole, 2-(5-bromo-2-hydroxyphenyl)-4(5)-methylimidazole, 2-(5-bromo-2-hydroxyphenyl)-4(5)-ethylimidazole, 2-(5-bromo-2-hydroxyphenyl)-4,5-dimethylimidazole, 2-(5-bromo-2-hydroxyphenyl)-4(5)-phenylimidazole, 2-(5-bromo-2-hydroxyphenyl)-4,5-diphenylimidazole, and 2-(6-fluoro-2-hydroxy-3-methoxyphenyl)imidazole.

Further examples thereof include 2-(6-fluoro-2-hydroxy-3-methoxyphenyl)-4(5)-methylimidazole, 2-(6-fluoro-2-hydroxy-3-methoxyphenyl)-4(5)-ethylimidazole, 2-(6-fluoro-2-hydroxy-3-methoxyphenyl)-4,5-dimethylimidazole, 2-(6-fluoro-2-hydroxy-3-methoxyphenyl)-4(5)-phenylimidazole, 2-(6-fluoro-2-hydroxy-3-methoxyphenyl)-4,5-diphenylimidazole, 2-(1-hydroxynaphthalen-2-yl)imidazole, 2-(1-hydroxynaphthalen-2-yl)-4(5)-methylimidazole, 2-(1-hydroxynaphthalen-2-yl)-4(5)-ethylimidazole, 4,5-dimethyl-2-(1-hydroxynaphthalen-2-yl)imidazole, 2-(1-hydroxynaphthalen-2-yl)-4(5)-phenylimidazole, 4,5-diphenyl-2-(1-hydroxynaphthalen-2-yl)imidazole, 2-(2-hydroxynaphthalen-1-yl)imidazole, 2-(2-hydroxynaphthalen-1-yl)-4(5)-methylimidazole, 2-(2-hydroxynaphthalen-1-yl)-4(5)-ethylimidazole, 4,5-dimethyl-2-(2-hydroxynaphthalen-1-yl)imidazole, 2-(2-hydroxynaphthalen-1-yl)-4(5)-phenylimidazole, and 4,5-diphenyl-2-(2-hydroxynaphthalen-1-yl)imidazole.

Examples of the compound represented by the general formula (2) include, but are not limited to, the following imidazole compounds:
2-(2-hydroxyphenyl)benzimidazole, 2-(2-hydroxy-3-methylphenyl)benzimidazole, 2-(2-hydroxy-4-methylphenyl)benzimidazole, 2-(2-hydroxy-5-methylphenyl)benzimidazole, 2-(3-t-butyl-2-hydroxyphenyl)benzimidazole, 2-(4-fluoro-2-hydroxyphenyl)benzimidazole, 2-(4-chloro-2-hydroxyphenyl)benzimidazole, 2-(4-bromo-2-hydroxyphenyl)benzimidazole, 2-(2,3-dihydroxyphenyl)benzimidazole, 2-(2,5-dihydroxyphenyl)benzimidazole, 2-(2-hydroxy-4-methoxyphenyl)benzimidazole, 2-(2-hydroxy-3-methoxyphenyl)benzimidazole, 2-(2-hydroxy-5-methoxyphenyl)benzimidazole, 2-(2-hydroxy-6-methoxyphenyl)benzimidazole, 2-(3-ethoxy-2-hydroxyphenyl)benzimidazole, 2-(5-ethoxy-2-hydroxyphenyl)benzimidazole, 2-(4-allyl-2-hydroxy-3-methoxyphenyl)benzimidazole, 2-(4,6-dimethoxy-2-hydroxyphenyl)benzimidazole, 2-(5-fluoro-2-hydroxyphenyl)benzimidazole, 2-(5-chloro-2-hydroxyphenyl)benzimidazole, 2-(5-bromo-2-hydroxyphenyl)benzimidazole, 2-(6-fluoro-2-hydroxy-3-methoxyphenyl)benzimidazole, 2-(1-hydroxynaphthalen-2-yl)benzimidazole, 2-(2-hydroxynaphthalen-1-yl)benzimidazole, and 2-(2-hydroxyphenyl)benzimidazole-6-carboxylic acid.

Among them, the compound represented by the general formula (1) is preferably a compound in which both R₁ and R₂ are hydrogen atoms or have different substituents, more preferably, for example, 2-(2-hydroxyphenyl)imidazole, 2-(2-hydroxyphenyl)-4(5)-methylimidazole, 4-ethyl-(2-hydroxyphenyl)-5-methylimidazole, (2-hydroxyphenyl)-4-isopropyl-5-methylimidazole, 4-butyl-(2-hydroxyphenyl)-5-methylimidazole, or 2-(2-hydroxy-3(5)-methoxyphenyl)imidazole, further preferably 2-(2-hydroxyphenyl)imidazole, from the viewpoint of obtaining a homogenous epoxy resin composition owing to excellent solubility in the epoxy resin (A) or a solvent, and achieving reduced warpage of a cured product and high heat resistance.

The compound represented by the general formula (2) is preferably 2-(2-hydroxyphenyl)benzimidazole, 2-(2-hydroxy-3(5)-methoxyphenyl)benzimidazole, 2-(1-hydroxynaphthalen-2-yl)benzimidazole, 2-(2-hydroxynaphthalen-1-yl)benzimidazole, or 2-(2-hydroxyphenyl)benzimidazole-6-carboxylic acid, more preferably 2-(2-hydroxyphenyl)benzimidazole or 2-(2-hydroxy-3(5)-methoxyphenyl)benzimidazole, from the viewpoint of obtaining similar effects.

The epoxy resin composition of the present embodiment comprises the component (C), i.e., the compound represented by the general formula (1) and/or (2), as a catalyst, whereby, surprisingly, the warpage of a cured product is reduced, and even high heat resistance can be conferred. Such an effect cannot be readily predicted from the structure of the component (C). The present inventor has further studied effects of imidazole compounds having various structures in a course leading to the present invention. Nonetheless, a compound that reduces the warpage of a cured product and can confer even high heat resistance is only the component (C) of the present invention contained as a catalyst, and this effect is extraordinary.

The component (C) is a component that catalytically reacts with the component (A), i.e., the epoxy resin, and can exert the effect described above by mere addition into the epoxy resin composition. Therefore, unlike conventional approaches of reducing warpage, the present invention can bring about an effect of reducing warpage and produces an effect of largely being able to improve the degree of freedom of formulation for those skilled in the art, without adding an epoxy resin or a polymer having a soft skeleton or adding a high concentration of a filler.

In the epoxy resin composition of the present embodiment, the mechanism under which the addition of the compound as the component (C) mentioned above to the specific curing agent (component (B)) mentioned above can not only achieve stability and curability but reduces the warpage of a cured product and can exert even high heat resistance is presumably, but not intended to be limited to, as follows.

The component (C) has a structural feature of an imidazole structure that reacts with an epoxy group, the structure being substituted at position 2 of imidazole by a hydroxyphenyl group. As for the achievement of stability and curability, the formation of an intramolecular hydrogen bond between a reactive site nitrogen and its adjacent hydroxyphenyl group in imidazole, as described in Patent Literature 2, suppresses the nucleophilicity of nitrogen on imidazole at the time of storage, leading to stability, whereas the hydrogen bond is dissociated at the time of heating, leading to reaction.

As for reduction in warpage of a cured product and high heat resistance, it has been confirmed that as a result of studying various imidazole compounds that the component (C) for use in the epoxy resin composition of the present embodiment is markedly effective. This suggests that the component (C) plays a role as a chain transfer agent derived from its structural feature such that a proton for stabilization is donated to an anion formed in ring opening through the reaction of an epoxy group with imidazole, by a hydroxyphenyl group located close thereto. This suppresses uneven acute formation of high-molecular-weight products and local thickening in the neighborhood of the reactive site during polymerization reaction and can cause chain extension reaction throughout the system. Thus, thickening during curing occurs mildly and uniformly so that stress generated during curing is easily relaxed to reduce warpage in a cured product. Furthermore, since unreacted epoxy groups are unlikely to remain, a high cross-link density and high heat resistance are presumably attained.

In the case of using the compound as the component (C) mentioned above as a catalyst for the specific curing agent (component (B)) mentioned above, the effect described above can be further obtained. For example, the triazine skeleton-containing phenol-based curing agent or the cyanate ester-based curing agent has an amine group or a cyanate group, which reacts with an epoxy group, derived from its structure and therefore tends to deteriorate storage stability even in the absence of a catalyst. Thus, the degree of this deterioration is marked if a catalyst is blended therewith. As for the active ester curing agent, which is low reactive in itself with an epoxy group, it is important for exerting physical properties to blend a catalyst therewith and perform curing at a high temperature of 180° C. or higher. However, a general catalyst competitively causes self-polymerization reaction of an epoxy group before active ester sufficiently reacts at a curing temperature. Therefore, unreacted active ester groups remain easily.

On the other hand, the component (C) mentioned above can largely improve storage stability because of being derived from its structure even when the triazine skeleton-containing phenol-based curing agent or the cyanate ester-based curing agent is used. Furthermore, the component (C) functions as a chain transfer agent during reaction at a high temperature of 150° C. or higher or 180° C. or higher and thereby suppresses acute self-polymerization reaction of an epoxy group alone and can allow reaction of an epoxy group to progress efficiently with each curing agent (B). Therefore, unreacted functional groups are unlikely to remain, and the original heat resistance and strength of the composition tend to be sufficiently exerted. The component (C) uniformly catalyzes the reaction of the curing agent (B) with an epoxy group. Therefore, curing progresses without local concentration of stress, and an effect of reducing the warpage of a cured product can be further exerted.

In light of the mechanism mentioned above, a wide range of components (C) having a structural feature represented by the general formula (1) and/or (2), including those having various substitutions of functional groups, produce the advantageous effects of the present invention by use in combination with the curing agent (B).

The component (C), because of having an aromatic ring and having a hydroxy group, is excellent in compatibility with resins having an aromatic ring or polar solvents and can be favorably dissolved in various epoxy resins or solvents.

In general, solid dispersion-type imidazole compounds having reduced compatibility with an epoxy resin are generally known as highly stable imidazole compounds. However, such imidazole compounds might reduce uniform curability because of being solid. Other problems thereof are that, particularly, in the case of performing the step of adding a solvent and preparing a thin film, as in film-type adhesives, film formability is reduced due to particle residues; these compounds cannot be applied to ultrathin films; and even the solid dispersion-type compounds cannot produce stability by dissolution depending on the type of a solvent, for example. Thus, the component (C) for use in the epoxy resin composition of the present embodiment, which can achieve stability and reactivity while uniformly dissolved in resins or solvents, is suitable, particularly, for purposes using a solvent, such as film-type adhesives.

In the epoxy resin composition of the present embodiment, the mass ratio between the component (B) and the component (C) mentioned above is not particularly limited. The mass ratio of involatile components except for a solvent with the component (B) defined as 100 is preferably (component (B):component (C))=100:0.1 to 100:40, more preferably 100:0.5 to 100:30, further preferably 100:1 to 100:20, still further preferably 100:1.5 to 100:15, even further preferably 100:1.8 to 100:12, particularly preferably 100:2 to 100:10.

Within this range, unnecessary self-polymerization reaction of an epoxy resin by the component (C) can be prevented while an effect of accelerating the reaction of the component (B) by the component (C) is sufficiently obtained. Thus, the resulting cured product layer tends to be able to have much better heat resistance and strength because the cross-link density of the resulting cured product falls within a proper range.

The content of the component (C) in the whole epoxy resin composition of the present embodiment is not particularly limited and is preferably 0.005% by mass or more, more preferably 0.05% by mass or more, further preferably 0.1% by mass or more, still further preferably 0.15% by mass or more, even further preferably 0.2% by mass or more, in all involatile components except for a solvent from the viewpoint of obtaining sufficient curability. The content is preferably 10% by mass or less, more preferably 5% by mass or less, further preferably 4% by mass or less, still further preferably 3% by mass or less, even further preferably 2% by mass or less, from the viewpoint of keeping a curing rate proper and maintaining the homogeneity of a cured product layer. However, the component (C) catalytically reacts with the component (A), i.e., the epoxy resin. Therefore, those skilled in the art can set a proper amount in consideration of the material or composition used and desired performance.

### (Component (D): Filler)

The epoxy resin composition of the present embodiment may further comprise a filler (hereinafter, also referred to as a filler (D) or a component (D)).

The filler (D) is not particularly limited and is one or two or more members selected from the group consisting of an inorganic filler and an inorganic filler treated in advance with a silane coupling agent (H) mentioned later, from the viewpoint of reducing warpage as well as an organic filler from the viewpoint of improving adhesion strength and improving crack resistance.

One of these fillers may be used singly, or two or more thereof may be used in combination.

The filler (D) is not particularly limited by its shape and may be in any form, for example, an amorphous, spherical, or scale-like form.

It is preferred to comprise an inorganic filler from the viewpoint of allowing the epoxy resin composition of the present embodiment and an adherend base material to have similar coefficients of linear expansion, and reducing warpage.

Examples of the inorganic filler include, but are not limited to, ceramics such as silica, alumina, glass, cordierite, silicone oxide, barium sulfate, barium carbonate, talc, clay, mica powders, zinc oxide, hydrotalcite, boehmite, aluminum hydroxide, magnesium hydroxide, calcium carbonate, magnesium carbonate, magnesium oxide, boron nitride, aluminum nitride, manganese nitride, aluminum borate, strontium carbonate, strontium titanate, calcium titanate, magnesium titanate, bismuth titanate, titanium oxide, zirconium oxide, barium titanate, barium zirconate titanate, barium zirconate, calcium zirconate, zirconium phosphate, and zirconium tungstate phosphate, carbons such as carbon nanotube and graphene, metals or alloys such as gold, silver, copper, nickel, aluminum, zinc, tin, lead, solder, indium, and palladium, and particles of polymer core materials coated with metal thin films.

Among them, it is preferred to comprise silica from the viewpoint of more reducing the warpage of a cured product. Examples of the silica include amorphous silica, fused silica, crystalline silica, synthetic silica, and hollow silica. Its shape is more preferably a spherical shape from the viewpoint of favorable filling properties or handleability of the epoxy resin composition.

Examples of the commercially available spherical fused silica include trade names: SO-C2, SO-C1, SO-E2, and SO-E1 manufactured by Admatechs Co., Ltd.

The average particle size of the filler (D) is not particularly limited and is preferably 3 μm or smaller, more preferably 2 μm or smaller, further preferably 1 μm or smaller, 0.7 μm or smaller, 0.5 μm or smaller, 0.4 μm or smaller, or 0.3 μm or smaller, from the viewpoint of being able to form a cured product layer using the epoxy resin composition containing the component (D) and form fine wiring on the cured product layer.

On the other hand, the average particle size of the component (D), i.e., the filler, is preferably 0.01 μm or larger, more preferably 0.03 μm or larger, further preferably 0.05 μm or larger, 0.07 μm or larger, or 0.1 μm or larger, from the viewpoint of attaining a moderate viscosity and preparing a resin paste having favorable handleability in forming a resin paste using the epoxy resin composition.

The average particle size of the filler can be measured by a laser diffraction/scattering method based on the Mie scattering theory. Specifically, the particle size distribution of the filler is prepared on a volume basis with a laser diffraction particle size distribution analyzer, and a median size thereof can be measured as the average particle size. For example, trade name: HELOS manufactured by Sympatec GmbH can be used as the laser diffraction particle size distribution analyzer.

In the case of using the inorganic filler as the filler (D), the content of the inorganic filler in the epoxy resin composition of the present embodiment can be appropriately set depending on desired performance and is not particularly limited. The content is preferably 5 to 98% by mass, more preferably 10 to 95% by mass, further preferably 15 to 90% by mass, still further preferably 20 to 88% by mass, even further preferably 25 to 85% by mass, particularly preferably 30 to 80% by mass, in all involatile components except for a solvent.

Within this range, the epoxy resin composition and the film-type adhesive of the present embodiment can further exert effects (i) to (iii): (i) a proper viscosity can be kept, and handleability is excellent, (ii) the amounts of a resin component and the inorganic filler fall within right ranges so that adhesion, close contact, and dimensional stability are excellent, and (iii) warpage, heat resistance, and breaking strength are excellent when the resin composition is cured.

The organic filler has a function as an impact-resistant relaxing agent having stress relaxing properties. The epoxy resin composition of the present embodiment contains the organic filler, whereby adhesion to various connection members can be further improved, and the generation and progression of fillet cracks tend to be able to be suppressed.

Examples of the organic filler include, but are not limited to, acrylic resins, silicone resins, butadiene rubber, polyester, polyurethane, polyvinyl butyral, polyarylate, polymethyl methacrylate, acrylic rubber, polystyrene, acrylonitrile-butadiene rubber (NBR), styrene-butadiene rubber (SBR), silicone-modified resins, and organic fine particles of copolymers containing these components.

The organic fine particles are preferably, for example, an alkyl (meth)acrylate-butadiene-styrene copolymer, an alkyl (meth)acrylate-silicone copolymer, a silicone-(meth)acrylic copolymer, a composite of silicone and (meth)acrylic acid, a composite of alkyl (meth)acrylate-butadiene-styrene and silicone, or a composite of alkyl (meth)acrylate and silicone, from the viewpoint of improvement in adhesion.

Organic fine particles having a core-shell structure where a core layer and a shell layer differ in composition can also be used as the organic filler.

Examples of the core-shell organic fine particles include, but are not particularly limited to, particles of acrylic resins grafted to silicone-acrylic rubber as a core, and particles of acrylic resins grafted to acrylic copolymers.

The modulus of elasticity is reduced by the contained core-shell organic fine particles, whereby stress generated in a fillet moiety is reduced, and fillet cracks tend to be able to be prevented. If fillet cracks occur, the contained core-shell organic fine particles act as a stress relaxing agent and tend to suppress the progression of the fillet cracks.

A material excellent in softness is preferably used as a material constituting the core layer. Examples of the material constituting the core layer include, but are not limited to, silicone-based elastomers, butadiene-based elastomers, styrene-based elastomers, acrylic elastomers, polyolefin-based elastomers, and silicone/acrylic composite-based elastomers.

On the other hand, a material constituting the shell layer is preferably a material excellent in affinity for other components of a semiconductor resin sealing material, particularly, affinity for an epoxy resin. Examples of the material constituting the shell layer include, but are not particularly limited to, acrylic resins and epoxy resins. Among them, an acrylic resin is particularly preferred from the viewpoint of affinity for other components of a semiconductor resin sealing material, particularly, affinity for an epoxy resin.

In the case of using the organic filler as the filler (D), the content of the organic filler in the epoxy resin composition of the present embodiment can be appropriately set depending on desired performance and is not particularly limited. The content is preferably 1 to 20% by mass, more preferably 2 to 18% by mass, further preferably 3 to 16% by mass, with respect to the total amount of the epoxy resin composition.

The content of the organic filler is 1% by mass or more, whereby stress relaxation works, and an effect of improving adhesive force tends to be obtained.

The content of the organic filler is 20% by mass or less, whereby an effect of thermal reflow resistance tends to be obtained.

### (Component (E): Solvent)

The epoxy resin composition of the present embodiment may further comprise a solvent (hereinafter, also referred to as a solvent (E) or a component (E)).

The epoxy resin composition of the present embodiment comprises the solvent (E), whereby the compound as the component (C) mentioned above tends to be homogeneously dissolved in the epoxy resin composition. This can improve uniform curability of a cured product layer made of the epoxy resin composition of the present embodiment. Furthermore, performance such as reduction in warpage and high heat resistance tends to be able to be further exerted by using the solvent (E) and also selecting components (C) having various structures depending on a desired reaction temperature zone or reaction rate.

The solvent (E) is not particularly limited, and a known solvent can be used.

Examples of the solvent (E) include, but are not limited to: hydrocarbons such as benzene, toluene, xylene, cyclohexane, mineral spirits, and solvent naphtha, ketones such as acetone, methyl ethyl ketone (MEK), methyl isopropyl ketone, methyl isobutyl ketone, cyclohexanone, and acetophenone; esters such as ethyl acetate, n-butyl acetate, propylene glycol monomethyl ethyl ether acetate, and γ-butyrolactone; alcohols such as methanol, ethanol, isopropanol, n-butanol, butyl cellosolve, butyl carbitol, 2-phenoxyethanol, and 1-methoxy-2-propanol; and amide-based solvents such as dimethylformamide, dimethylacetamide, and N-methylpyrrolidone.

One of these solvents may be used singly, or two or more thereof may be used in combination.

The content of the solvent (E) in the epoxy resin composition of the present embodiment is not particularly limited. In the case of blending the solvent therewith for use as a varnish or a paste, the content is preferably 5 to 80% by mass, more preferably 10 to 75% by mass, further preferably 15 to 70% by mass, still further preferably 20 to 65% by mass, even further preferably 25 to 60% by mass, with respect to the whole epoxy resin composition from the viewpoint of attaining favorable handleability by uniformly dissolving various components and controlling a viscosity to a proper range.

When other components contain a solvent, for example, when the component (B) contains a solvent, the content also includes such a solvent and is in a preferred range of the proportion of the solvent in the whole epoxy resin composition.

In the case of preparing the epoxy resin composition of the present embodiment into a film-type adhesive, the content of the solvent (E) is not particularly limited and is preferably 10% by mass or less, more preferably 8% by mass or less, further preferably 6% by mass or less, with respect to the whole epoxy resin composition from the viewpoint of suppressing air bubble formation. On the other hand, the content is preferably 0.001% by mass or more, more preferably 0.01% by mass or more, further preferably 0.1% by mass or more, with respect to the whole epoxy resin composition from the viewpoint of preventing the close contact or flexibility of the film-type adhesive from being reduced due to excessive reduction in amount of the solvent.

### (Component (F): Additional Curing Agent)

The epoxy resin composition of the present embodiment may further comprise a curing agent other than the component (B), i.e., the predetermined curing agent (B), and the component (C), i.e., the compound of the general formula (1) and/or (2) (hereinafter, also referred to as a curing agent (F) or a component (F)).

Conventionally known curing agents for use in epoxy resins can be widely used as the component (F). Examples thereof include, but are not particularly limited to, amine-based curing agents, amide-based curing agents, phenol-based curing agents (except for triazine skeleton-containing phenol-based curing agents), acid anhydride-based curing agents, imidazole-based curing agents (except for the component (C)), carbodiimide-based curing agents, benzoxazine-based curing agents, phosphorus-based curing agents, thiol-based curing agents, catalyst-type curing agents, and their modified products.

One of these curing agents may be used singly, or two or more thereof may be used in combination.

Examples of the amine-based curing agent include, but are not limited to, aliphatic amine, aromatic amine, 4-dimethylaminopyridine, benzyldimethylamine, 2,4,6,-tris(dimethylaminomethyl)phenol, and 1,8-diazabicyclo(5,4,0)-undecene.

Examples of the aliphatic amine include, but are not limited to, triethylamine, tributylamine, diethylenetriamine, triethylenetetraamine, tetraethylenepentamine, m-xylenediamine, trimethylhexamethylenediamine, 2-methylpentamethylenediamine, isophoronediamine, 1,3-bisaminomethylcyclohexane, 1,4-bisaminomethylcyclohexane, bis(4-aminocyclohexyl)methane, norbornenediamine, and 1,2-diaminocyclohexane.

Examples of the aromatic amine include, but are not limited to, diaminodiphenylmethane, m-phenylenediamine, diaminodiphenylsulfone, diethyltoluenediamine, trimethylenebis(4-amino benzoate), polytetramethylene oxide-di-p-amino benzoate, trade name: KAYAHARD A-A manufactured by Nippon Kayaku Co., Ltd., and trade name: ETACURE 100 manufactured by Mitsui Fine Chemicals, Inc.

Examples of the amide-based curing agent include, but are not limited to, dicyandiamide and its derivative guanidine compounds, acid anhydride adducts of amine-based curing agents, and hydrazide compounds.

Examples of the hydrazide-based curing agent composed of the hydrazide compound include, but are not limited to, dihydrazide succinate, dihydrazide adipate, dihydrazide phthalate, dihydrazide isophthalate, dihydrazide terephthalate, hydrazide p-oxybenzoate, hydrazide salicylate, hydrazide phenylaminopropionate, and dihydrazide maleate.

Examples of the guanidine-based curing agent composed of the guanidine compound include, but are not limited to, dicyandiamide, dicyandiamide derivatives such as dicyandiamide-aniline adducts, dicyandiamide-methylaniline adducts, dicyandiamide-diaminodiphenylmethane adducts, and dicyandiamide-diamino diphenyl ether adducts, guanidine salts such as guanidine nitrate, guanidine carbonate, guanidine phosphate, guanidine sulfamate, and aminoguanidine bicarbonate, methylguanidine, ethylguanidine, propylguanidine, butylguanidine, dimethylguanidine, trimethylguanidine, tetramethylguanidine, pentamethylguanidine, cyclohexylguanidine, phenylguanidine, diphenylguanidine, toluylguanidine, acetylguanidine, diacetylguanidine, propionylguanidine, dipropionylguanidine, cyanoacetylguanidine, guanidine succinate, diethylcyanoacetylguanidine, dicyandiamidine, N-oxymethyl-N′-cyanoguanidine, N,N′-dicarboethoxyguanidine, 1,5,7-triazabicyclo[4.4.0]dec-5-ene, 7-methyl-1,5,7-triazabicyclo[4.4.0]dec-5-ene, 1-methylbiguanide, 1-ethylbiguanide, 1-n-butylbiguanide, 1-n-octadecylbiguanide, 1,1-dimethylbiguanide, 1,1-diethylbiguanide, 1-cyclohexylbiguanide, 1-allylbiguanide, 1-phenylbiguanide, and 1-(o-tolyl)biguanide.

Examples of the phenol-based curing agent (except for triazine skeleton-containing phenol-based curing agents) include, but are not limited to, phenol novolac resin, bisphenol A novolac resin, cresol novolac resin, phenol aralkyl resin, cresol aralkyl resin, naphthol-phenol co-condensed novolac resin, naphthol-cresol co-condensed novolac resin, allyl acryl phenol resin, dicyclopentadiene skeleton-containing phenol resin, biphenyl skeleton-containing phenol resin, and naphthalene skeleton-containing phenol resin.

Examples of the commercially available phenol-based curing agent include trade names: TD2090 (phenol novolac resin) and EXB-9500 (naphthalene skeleton-containing phenol resin) manufactured by DIC Corp., trade names: HF-1M (phenol novolac resin), MEH-7700, MEH-7810, and MEH-7851 (biphenyl skeleton-containing phenol resin) manufactured by UBE Corp., trade names: NHN, CBN, and GPH (naphthalene skeleton-containing phenol resin) manufactured by Nippon Kayaku Co., Ltd., and trade names: SN170, SN180, SN190, SN475, SN485, SN495, SN375, and SN395 (naphthalene skeleton-containing phenol resin) manufactured by NIPPON STEEL Chemical & Material Co., Ltd.

Among them, it is preferred to comprise a phenol-based curing agent having a bisphenol A-type structure, a bisphenol F-type structure, a bisphenol AF-type structure, a naphthalene structure, a phenol novolac structure, a cyclohexane structure, a cyclohexanedimethanol structure, a butadiene structure, a biphenyl-type structure, a bixylenol structure, a cresol novolac structure, a dicyclopentadiene structure, a trisphenol structure, a naphthol structure, a naphthylene ether structure, an anthracene structure, a tetraphenylethane structure, a bisphenol acetophenone structure, or a fluorene structure from the viewpoint of favorable heat resistance and strength of a cured product.

Examples of the acid anhydride-based curing agent include, but are not limited to, phthalic anhydride, trimellitic anhydride, pyromellitic anhydride, maleic anhydride, tetrahydrophthalic anhydride, methyltetrahydrophthalic anhydride, methylnadic anhydride, hexahydrophthalic anhydride, and methylhexahydrophthalic anhydride.

Examples of the imidazole-based curing agent except for the component (C) include, but are not limited to, 2-methylimidazole, 2-undecylimidazole, 2-heptadecylimidazole, 1,2-dimethylimidazole, 2-ethyl-4-methylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazolium trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine-isocyanuric acid adducts, 2-phenylimidazole-isocyanuric acid adducts, 2-phenyl-4,5-dihydroxymethylimidazole, 2-phenyl-4-methyl-5-hydroxymethylimidazole, 2,3-dihydro-1H-pyrrolo[1,2-a]benzimidazole, 1-dodecyl-2-methyl-3-benzylimidazolium chloride, 2-methylimidazoline, and 2-phenylimidazoline.

Examples of the carbodiimide-based curing agent include, but are not limited to, trade names: CARBODILITE V-02B, V-03, V-04K, V-07, and V-09 manufactured by Nisshinbo Chemical Inc., and trade name: STABAXOL P, P400, and HAICADIL 510 manufactured by Rhein Chemie Corp. A modified product of a carbodiimide compound as disclosed in Japanese Patent No. 7226954 may be used.

Examples of the benzoxazine-based curing agent include, but are not limited to, trade name: HFB2006M manufactured by Showa HighPolymer Co., Ltd., and trade names: P-d, F-a, and ALP-d manufactured by Shikoku Kasei Holdings Corp.

Examples of the phosphorus-based curing agent include, but are not limited to, triphenylphosphine, phosphonium borate compounds, tetraphenylphosphonium tetraphenyl borate, n-butylphosphonium tetraphenyl borate, tetrabutylphosphonium decanoate, (4-methylphenyl)triphenylphosphonium thiocyanate, tetraphenylphosphonium thiocyanate, and butyltriphenylphosphonium thiocyanate.

The thiol-based curing agent can contain two or more thiol groups in one molecule. Examples thereof include, but are not limited to, 3,3′-dithiodipropionic acid, trimethylolpropane tris(thioglycolate), pentaerythritol tetrakis(thioglycolate), ethylene glycol dithioglycolate, 1,4-bis(3-mercaptobutyryloxy)butane, tris[(3-mercaptopropionyloxy)-ethyl]-isocyanurate, 1,3,5-tris(3-mercaptobutyloxyethyl)-1,3,5-triazine-2,4,6(1H,3H,5H)-trione, trimethylolpropane tris(3-mercaptopropionate), pentaerythritol tetrakis(3-mercaptopropionate), pentaerythritol tetrakis(3-mercaptobutyrate), dipentaerythritol hexakis(3-mercaptopropionate), 1,3,4,6-tetrakis(2-mercaptoethyl) glycoluril, 4-butanedithiol, 1,6-hexanedithiol, and 1,10-decanedithiol. The thiol-based curing agent is preferably 1,4-bis(3-mercaptobutyryloxy)butane, 1,3,5-tris(3-mercaptobutyloxyethyl)-1,3,5-triazine-2,4,6(1H,3H,5H)-trione, pentaerythritol tetrakis(3-mercaptopropionate), or pentaerythritol tetrakis(3-mercaptobutyrate) from the viewpoint of the impact resistance of a cured product of the epoxy resin composition of the present embodiment, more preferably pentaerythritol tetrakis(3-mercaptopropionate), pentaerythritol tetrakis(3-mercaptobutyrate) from the viewpoint of the low-temperature curability of the epoxy resin composition of the present embodiment.

Examples of the catalyst-type curing agent include, but are not limited to, cationic thermosetting catalysts and BF₃-amine complexes.

Examples of the modified product serving as the curing agent include, but are not limited to, polyamine compounds, amine-epoxy adducts, amine-urea adducts, imidazole-epoxy adducts, aminimide compounds, and microcapsule-type curing agents prepared by coating these compounds and curing agents prepared by adsorbing these compounds onto porous materials. Specific examples thereof include, but are not limited to, trade names: NOVACURE HX-3722, HX-3742, HX-3088, HX-3613, HXA3932HP, HXA9322HP, HXA9382HP, and HXA9192HP manufactured by Asahi Kasei Corp., trade names: AMICURE PN-23J, PN-40J, and MY-24 manufactured by Ajinomoto Fine-Techno Co., Inc., and trade names: FUJICURE FXR-1020 and FXR-1030 manufactured by Fuji Kasei Kogyo Co., Ltd.

Among those described above, it is preferred to comprise a carbodiimide-based curing agent as the component (F), for example, from the viewpoint of improving the close contact of the epoxy resin composition of the present embodiment with a substrate material and sufficiently exerting cured product strength by elevating a cross-link density through reaction with various active hydrogen groups. It is also preferred to comprise a benzoxazine-based curing agent from the viewpoint of obtaining a cured product excellent in high dimensional stability, high flame retardancy, low dielectric dissipation factor, and low water absorbing properties.

The content of the component (F) in the epoxy resin composition of the present embodiment can be appropriately set depending on the reactivity of the component (B) or the component (C) mentioned above and desired performance and is not particularly limited. The content is preferably 0.01% by mass or more, more preferably 0.1% by mass or more, further preferably 1.0% by mass or more, in all involatile components except for a solvent from the viewpoint of obtaining favorable reactivity. The content is preferably 40% by mass or less, more preferably 30% by mass or less, further preferably 20% by mass or less, from the viewpoint of obtaining favorable storage stability.

### (Component (G): Thermoplastic Resin)

The epoxy resin composition of the present embodiment may further comprise a thermoplastic resin (hereinafter, also referred to as a, thermoplastic resin (G) or a component (G)).

The epoxy resin composition of the present embodiment comprises the thermoplastic resin (G), whereby in the case of molding the epoxy resin composition of the present embodiment into a film by casting or by coating and drying at a given thickness, cracks or breakage is prevented, and the film shape can be maintained.

Examples of the thermoplastic resin (G) include, but are not limited to, phenoxy resins, polyvinylacetal resins, acid anhydride group-containing vinyl resins, polyolefin resins, polybutadiene resins, polyimide resins, polyamideimide resins, styrene-based elastomer resins, polyethersulfone resins, polyphenylene ether resins, polysulfone resins, and acrylic resins.

One of these thermoplastic resins (G) may be used singly, or two or more thereof may be used in combination.

The weight-average molecular weight of the thermoplastic resin (G) is preferably 10000 or higher, more preferably 15000 or higher, further preferably 20000 or higher, still further preferably 25000 or higher, even further preferably 30000 or higher, from the viewpoint of obtaining a cured product layer having sufficient strength using the epoxy resin composition of the present embodiment. The upper limit of the weight-average molecular weight of the thermoplastic resin (G) is preferably 200000 or lower, more preferably 180000 or lower, further preferably 160000 or lower, still further preferably 150000 or lower, from the viewpoint of obtaining favorable compatibility. The weight-average molecular weight of the thermoplastic resin (G) can be measured by, for example, gel permeation chromatography (GPC). Specifically, the weight-average molecular weight (polystyrene-based) of the thermoplastic resin can be calculated by using HLC-8320GPC manufactured by Tosoh Corp. as a measurement apparatus, Shodex KF-804/KF-803/KF-802/KF-802 manufactured by Resonac Corp. as a column, and tetrahydrofuran or the like as a mobile phase, performing measurement at a column temperature of 40° C., and using a calibration curve of standard polystyrene.

The thermoplastic resin (G) preferably has a functional group containing one or more atoms selected from the group consisting of an oxygen atom, a nitrogen atom, and a sulfur atom, or a carbon-carbon double bond, from the viewpoint of elevating the cross-link density of a cured product of the epoxy resin composition of the present embodiment and attaining sufficient heat resistance and strength of a cured product layer. The functional group is one or more members selected from the group consisting of a hydroxy group, a carboxy group, an acid anhydride group, an epoxy group, an amino group, a thiol group, an enol group, an enamine group, a urea group, a cyanate group, an isocyanate group, a thioisocyanate group, a diimide group, an alkenyl group, an arene group, and a ketene group. The acid anhydride group is preferably a carboxylic anhydride group. Preferred examples of the alkenyl group include a vinyl group, an allyl group, and a styryl group. When the thermoplastic resin contains such a functional group, the functional group equivalent of the thermoplastic resin (G) is preferably 100000 or less, more preferably 90000 or less, 80000 or less, 70000 or less, 60000 or less, 50000 or less, 40000 or less, 30000 or less, 20000 or less, 10000 or less, 8000 or less, 6000 or less, or 5000 or less. The lower limit of the functional group equivalent is not particularly limited and can be usually 50 or more or 100 or more, for example.

Hereinafter, suitable thermoplastic resins (G) will be described in more detail. Thermoplastic resin prepared by further adding the functional groups described above to the following thermoplastic resins can also be suitably used as the component (G) according to known procedures.

Preferred examples of the phenoxy resin include phenoxy resins having one or more skeletons selected from the group consisting of a bisphenol A skeleton, a bisphenol F skeleton, a bisphenol S skeleton, a bisphenol acetophenone skeleton, a phenol novolac skeleton, a biphenyl skeleton, a fluorene skeleton, a dicyclopentadiene skeleton, a norbornene skeleton, a naphthalene skeleton, an anthracene skeleton, an adamantane skeleton, a terpene skeleton, and a trimethylcyclohexane skeleton. The phenoxy resin may have any terminal functional group such as a phenolic hydroxy group or an epoxy group.

Specific examples of the phenoxy resin include trade names: 1256, 4250 (bisphenol A skeleton-containing phenoxy resin), YX8100 (bisphenol S skeleton-containing phenoxy resin), YX6954, YX6954BH30 (bisphenol acetophenone skeleton-containing phenoxy resin), YX7553, YX7553BH30 (biscresol fluorenone skeleton-containing phenoxy resin), YL6794 (terpene skeleton-containing phenoxy resin), YL7213, YL7290 (trimethylcyclohexane skeleton-containing phenoxy resin), YL7500BH30, YL7769BH30, and YL7482 manufactured by Mitsubishi Chemical Group Corp., and trade names: FX280 and FX293 (bisphenol fluorenone skeleton-containing phenoxy resin) manufactured by NIPPON STEEL Chemical & Material Co., Ltd.

Specific examples of the polyvinylacetal resin include trade names: Denka Butyral 4000-2, 5000-A, 6000-C, and 6000-EP from Denka Co., Ltd., and trade names: SLEC BH series, BX series, KS series (e.g., KS-1), BL series, and BM series manufactured by Sekisui Chemical Co., Ltd.

Examples of the acid anhydride group-containing vinyl resin include copolymers of an acid anhydride group-containing monomer (d1) and an additional monomer (d2). Examples of the acid anhydride group-containing monomer (d1) include maleic anhydride, itaconic anhydride, citraconic anhydride, and aconitic anhydride. The additional monomer (d2) is not particularly limited as long as the monomer is copolymerizable with the acid anhydride group-containing monomer (d1). Examples thereof include ethylenic unsaturated monomers such as (meth)acrylic acid, (meth)acrylic acid ester, and styrene. Specific examples of the acid anhydride group-containing vinyl resin include trade names: EF-30, EF-40, EF-60, and EF-80 manufactured by Cray Valley SA.

Specific examples of the polyimide resin include trade names: RICACOAT SN-20 and PN-20 manufactured by New Japan Chemical Co., Ltd., and trade name: UNIDIC V-8000 manufactured by DIC Corp.

Specific examples of the polyimide resin also include modified polyimide such as linear polyimide obtained by reacting bifunctional hydroxyl group-terminated polybutadiene, a diisocyanate compound, and tetrabasic anhydride (Japanese Patent Laid-Open No. 2006-37083) and polysiloxane skeleton-containing polyimide (Japanese Patent Laid-Open No. 2002-12667, Japanese Patent Laid-Open No. 2000-319386, International Publication No. WO 2010/53186, etc.).

Specific examples of the polyamideimide resin include trade names: VYLOMAX HR11NN and HR16NN manufactured by Toyobo Co., Ltd., and trade names: HPC-5020, HPC-6000, HPC-7200, and HPC-9000 manufactured by Resonac Corp.

Examples of the styrene-based elastomer resin include block copolymers comprising a block of styrene or its analog as at least one terminal block and comprising an elastomer block of conjugated diene or its hydrogenated product as at least one intermediate block. Specific examples thereof include styrene-butadiene diblock copolymers, styrene-butadiene triblock copolymers, styrene-isoprene diblock copolymers, styrene-isoprene triblock copolymers, hydrogenated styrene-butadiene diblock copolymers, hydrogenated styrene-butadiene triblock copolymers, hydrogenated styrene-isoprene diblock copolymers, hydrogenated styrene-isoprene triblock copolymers, and hydrogenated styrene-butadiene random copolymers. Specific examples of the styrene-based elastomer resin include trade names: ASAPRENE, TUFPRENE, and ASAPLEX manufactured by Asahi Kasei Corp., and trade names: HYBRAR and SEPTON manufactured by Kuraray Co., Ltd.

Specific examples of the polyethersulfone resin include trade name: PES5003P manufactured by Sumitomo Chemical Co., Ltd.

Specific examples of the polysulfone resin include trade names: Polysulfone P1700 and P3500 manufactured by Solvay Advanced Polymers, LLC.

Specific examples of the polybutadiene resin include trade names: G-1000, G-3000, GI-1000, and GI-3000 manufactured by Nippon Soda Co., Ltd., trade name: R-45EPI manufactured by Idemitsu Petrochemical Co., Ltd., trade name: EPOFRIEND AT501 manufactured by Daicel Corp., and trade names: Ricon 130, Ricon 142, Ricon 150, Ricon 657, and Ricon 130MA manufactured by Cray Valley SA.

Specific examples of the acrylic resin include trade names: SG-P3, SG-600LB, SG-280, SG-790, and SG-K2 manufactured by Nagase ChemteX Corp., and trade names: SN-50, AS-3000E, and ME-2000 manufactured by Negami Chemical Industrial Co., Ltd.

Among them, it is preferred to comprise, as the thermoplastic resin (G), one or more members selected from the group consisting of a phenoxy resin, a polyvinylacetal resin, an acid anhydride group-containing vinyl resin, a polyimide resin, a polyamideimide resin, a styrene-based elastomer resin, and an acrylic resin from the viewpoint of securing long-term connection reliability through sufficient heat resistance and strength of a cured product layer obtained using the epoxy resin composition of the present embodiment, and securing uniform curability by keeping compatibility proper with the epoxy resin (A).

In the case of applying the epoxy resin composition of the present embodiment to, for example, a material to be integrated in a bent form into an electronic device, such as a flexible wiring board, the contained thermoplastic resin (G) can attain reduction in elasticity of a cured product layer of the epoxy resin composition and can suppress fracturing or peeling. For purposes requiring such reduction in elasticity, it is preferred to comprise, as the thermoplastic resin (G), but not limited to, a resin having one or more structures selected from a polybutadiene structure, a polysiloxane structure, a poly(meth)acrylate structure, a polyalkylene structure, a polyalkyleneoxy structure, a polyisoprene structure, a polyisobutylene structure, and a polycarbonate structure in a molecule because an effect of reducing elasticity is easily obtained. A thermoplastic resin that has a glass transition temperature of 25° C. or lower or is in a liquid state at 25° C. can also be suitably used from the viewpoint of obtaining the effect of reducing elasticity.

The content of the thermoplastic resin (G) in the epoxy resin composition of the present embodiment can be appropriately set depending on the contents and types of the epoxy resin (A), the curing agent (B), and the additional curing agent used, the content of the filler (D), and desired performance of the epoxy resin composition of the present embodiment and is not particularly limited. The content is preferably 0.5% by mass or more, more preferably 1% by mass or more, further preferably 1.2% by mass or more, still further preferably 1.5% by mass or more, in all involatile components except for a solvent from the viewpoint of securing the close contact and flexibility of the epoxy resin composition of the present embodiment. The content is preferably 50% by mass or less, more preferably 40% by mass or less, further preferably 30% by mass or less, still further preferably 20% by mass or less, from the viewpoint of keeping heat resistance and strength favorable for the epoxy resin composition of the present embodiment.

### (Component (H): Silane Coupling Agent)

The epoxy resin composition of the present embodiment may further comprise a silane coupling agent (hereinafter, also referred to as a silane coupling agent (H) or a component (H)).

It is preferred to comprise the silane coupling agent (H) because favorable affinity can be attained between a resin component and the filler or between a resin component and an adherend substrate, uniform dispersibility of the filler component is improved, and the adhesion of the epoxy resin composition tends to be improved.

In the present embodiment, the phrase “comprise a silane coupling agent (H)” means that in a process of obtaining the epoxy resin composition of the present embodiment, the silane coupling agent is integrated into the composition of the epoxy resin composition by any of the following methods (i) to (iii).

### Method (i):

A method of treating the filler (D) with the silane coupling agent and blending the filler thus treated into the epoxy resin composition.

### Method (ii):

A method of directly adding the silane coupling agent to the epoxy resin composition (integral blend method).

Method (iii):

A method of reacting the silane coupling agent with an end or a side chain of the epoxy resin (A) or the thermoplastic resin (G) used, or blending a silylated resin using a resin of a monomer copolymerized with the silane coupling agent, for example.

Any of the methods (i) to (iii) mentioned above may be used. The method (i) is preferred from the viewpoint that an alcohol serving as a by-product of silane coupling reaction is unlikely to remain in the system and from the viewpoint that the filler has much better dispersibility. The method (ii) or (iii) is preferred from the viewpoint that affinity can be allowed to act between the resin and the filler as well as between the resin and an adherend substrate, and adhesion and close contact can be more favorable.

The silane coupling agent (H) contains at least one hydrolyzable group such as an alkoxy group or an aryloxy group bonded to a silicon atom, and in addition to this, an alkyl group, an alkenyl group, or an aryl group may be bonded thereto. The alkyl group may be substituted by an amino group, an alkoxy group, an epoxy group, or a (meth)acryloyloxy group.

It is preferred to comprise, as the silane coupling agent (H), one or more silane coupling agents selected from, for example, but not limited to, an aminosilane-based coupling agent, an epoxysilane-based coupling agent, a mercaptosilane-based coupling agent, a styrylsilane-based coupling agent, an acrylate silane-based coupling agent, an isocyanate silane-based coupling agent, a sulfide silane-based coupling agent, a vinylsilane-based coupling agent, a silane-based coupling agent, an organosilazane compound, and a titanate-based coupling agent, from the viewpoint of improvement in uniform dispersibility of the filler component and improvement in adhesion and close contact of the resin composition.

Specific examples of the silane coupling agent (H) include aminosilane-based coupling agents such as 3-aminopropyltrimethoxysilane, 3-aminopropyltriethoxysilane, 3-aminopropyldiethoxymethylsilane, N-phenyl-3-aminopropyltrimethoxysilane, N-methylaminopropyltrimethoxysilane, N-2(-aminoethyl)-3-aminopropyltrimethoxysilane, and N-(2-aminoethyl)-3-aminopropyldimethoxymethylsilane, epoxysilane-based coupling agents such as 3-glycidyloxypropyltrimethoxysilane, 3-glycidyloxypropyltriethoxysilane, 3-glycidyloxypropylmethyldiethoxysilane, 3-glycidyloxypropyl(dimethoxy)methylsilane, glycidyl butyltrimethoxysilane, and 2-(3,4-epoxycyclohexyl)ethyltrimethoxysilane, mercaptosilane-based coupling agents such as 3-mercaptopropyltrimethoxysilane, 3-mercaptopropyltriethoxysilane, 3-mercaptopropylmethyldimethoxysilane, and 11-mercaptoundecyltrimethoxysilane, styrylsilane-based coupling agents such as p-styryltrimethoxysilane, acrylate silane-based coupling agents such as 3-acryloxypropyltrimethoxysilane, 3-methacryloxypropyltrimethoxysilane, 3-methacryloxypropyldimethoxysilane, 3-methacryloxypropyltriethoxysilane, and 3-methacryloxypropyldiethoxysilane, isocyanate silane-based coupling agents such as 3-isocyanatopropyltrimethoxysilane, sulfide silane-based coupling agents such as bis(triethoxysilylpropyl) disulfide and bis(triethoxysilylpropyl) tetra sulfide, silane-based coupling agents such as methyltrimethoxysilane, octadecyltrimethoxysilane, phenyltrimethoxysilane, methacryloxypropyltrimethoxysilane, imidazole silane, triazine silane, and t-butyltrimethoxysilane, organosilazane compounds such as hexamethyldisilazane, 1,3-divinyl-1,1,3,3-tetramethyldisilazane, hexaphenyldisilazane, trisilazane, cyclotrisilazane, octamethylcyclotetrasilazane, hexabutyldisilazane, hexaoctyldisilazane, 1,3-diethyltetramethyldisilazane, 1,3-di-n-octyltetramethyldisilazane, 1,3-diphenyltetramethyldisilazane, 1,3-dimethyltetraphenyldisilazane, 1,3-diethyltetramethyldisilazane, 1,1,3,3-tetraphenyl-1,3-dimethyldisilazane, 1,3-dipropyltetramethyldisilazane, hexamethylcyclotrisilazane, dimethylaminotrimethylsilazane, and tetramethyldisilazane, and titanate-based coupling agents such as tetra-n-butyl titanate dimers, titanium-i-propoxyoctylene glycolate, tetra-n-butyl titanate, titanium octylene glycolate, diisopropoxy titanium bis(triethanol aminate), dihydroxy titanium bislactate, dihydroxy bis(ammonium lactate) titanium, bis(dioctyl pyrophosphate) ethylene titanate, bis(dioctyl pyrophosphate) oxyacetate titanate, tri-n-butoxy titanium monostearate, tetra-n-butyl titanate, tetra(2-ethylhexyl) titanate, tetraisopropylbis(dioctyl phosphite) titanate, tetraoctylbis(ditridecyl phosphite) titanate, tetra(2,2-diallyloxymethyl-1-butyl)bis(ditridecyl)phosphite titanate, isopropyltrioctanoyl titanate, isopropyltricumylphenyl titanate, isopropyltriisostearoyl titanate, isopropylisostearoyl diacryltitanate, isopropyldimethacrylisostearoyl titanate, isopropyltri(dioctyl phosphate) titanate, isopropyltridodecylbenzenesulfonyl titanate, isopropyl tris(dioctyl pyrophosphate) titanate, and isopropyltri(N-amidoethyl/aminoethyl) titanate.

Among them, the silane coupling agent is preferably an aminosilane-based coupling agent, an epoxysilane-based coupling agent, a mercaptosilane-based coupling agent, or an organosilazane compound, more preferably an aminosilane-based coupling agent.

Examples of the commercially available product include trade names: KBM403 (3-glycidoxypropyltrimethoxysilane), KBM803 (3-mercaptopropyltrimethoxysilane), KBE903 (3-aminopropyltriethoxysilane), KBM573 (N-phenyl-3-aminopropyltrimethoxysilane), and SZ-31 (hexamethyldisilazane) manufactured by Shin-Etsu Chemical Co., Ltd.

The content of the silane coupling agent (H) in the epoxy resin composition of the present embodiment is not particularly limited and is preferably 0.1 to 2.0 parts by mass with respect to 100 parts by mass of the filler (D) from the viewpoint of suppressing excessive side reaction while attaining favorable dispersibility of the filler (D) and adhesion and close contact of the epoxy resin composition of the present embodiment.

### (Additive)

The epoxy resin composition of the present embodiment may further comprise, if necessary, an additive such as a diluent, a reactive diluent, a pigment, a dye, a flow adjuster, a thickener, a reinforcing agent, a mold release agent, a wetting agent, a flame retardant, a surfactant, a stabilizer, or an adhesion promoter, in addition to the components (A) to (H) mentioned above.

Examples of the diluent include, but are not limited to, dioctyl phthalate, dibutyl phthalate, and benzyl alcohol.

The reactive diluent is a compound having a reactive functional group capable of being integrated into a curing structure such as an epoxy group or an acrylic group, and is a compound effective for reducing the viscosity of the epoxy resin composition of the present embodiment by addition into the epoxy resin composition.

Examples of the reactive diluent include, but are not limited to, acrylate compounds and epoxy compounds capable of reducing a viscosity without impairing reactivity.

Examples of the acrylate compound serving as the reactive diluent include, but are not limited to, compounds having (meth)acryloyl groups at both ends of polyalkylene oxide, polyethylene glycol di(meth)acrylate, polypropylene glycol di(meth)acrylate, polybutylene glycol di(meth)acrylate, trimethylolpropane-type polyfunctional (meth)acrylate, pentaerythritol-type polyfunctional (meth)acrylate, and dipentaerythritol-type polyfunctional (meth)acrylate.

Examples of the epoxy compound serving as the reactive diluent include, but are not limited to, n-butyl glycidyl ether, tert-butyl glycidyl ether, diglycidyl aniline, N,N′-glycidyl-o-toluidine, phenyl glycidyl ether, cresyl glycidyl ether, p-tert-butyl phenyl glycidyl ether, styrene oxide, ethylene glycol diglycidyl ether, propylene glycol diglycidyl ether, and 1,6-hexanediol diglycidyl ether.

Various monoepoxy compounds or glycidyl ether compounds of polyhydric alcohols may be used as the reactive diluent. However, these compounds have, in one molecule, only one functional group (epoxy group or glycidyl group) that contributes to reaction with the component (B), the component (C), and the component (F), and tend to be unable to attain sufficient heat resistance or toughness of a cured product of the epoxy resin composition because these compounds cannot form a three-dimensional cross-link at the time of curing, though not responsible for voids by volatilization. Accordingly, the reactive diluent is preferably a compound containing two or more glycidyl groups in one molecule from the viewpoint of being able to form a three-dimensional cross-link at the time of curing and suppressing reduction in heat resistance or toughness at the time of curing.

One of these reactive diluents may be used singly, or two or more thereof may be used in combination.

The content of the reactive diluent can be appropriately set depending on desired performance of the epoxy resin composition of the present embodiment and is not particularly limited. The content is preferably 1.0 part by mass or more and 30 parts by mass or less with respect to 100 parts by mass of the epoxy resin (A). The content is 1.0 part by mass or more, whereby the viscosity of the epoxy resin composition of the present embodiment is prevented from being elevated at ordinary temperature, and deterioration in embedding properties tends to be able to be suppressed upon use as a film for wiring embedding. Furthermore, reduction in heat resistance or toughness is suppressed at the time of curing, and the generation and progression of fillet cracks tend to be able to be suppressed. On the other hand, the content of the reactive diluent is 30 parts by mass or less with respect to 100 parts by mass of the epoxy resin (A), whereby reduction in close contact is suppressed, and peeling tends to be suppressed at the time of a moisture reflow test. It is also preferred to further contain the reactive diluent for the purpose of suppressing elevation in viscosity resulting from high filling of the filler (D).

Examples of the pigment include, but are not limited to, kaolin, chalk powders, gypsum, antimony trioxide, penton, aerosol, lithopone, baryte, and titanium dioxide.

Examples of the dye include, but are not limited to, natural dyes including plant-derived dyes such as madder and indigo, and mineral-derived dyes such as ocher and bole, and synthetic dyes such as alizarin and indigo as well as fluorescent dyes.

Examples of the flow adjuster include, but are not limited to: organic titanium compounds such as titanium tetraisopropoxide and titanium diisopropoxy bis(acetylacetonate); and organic zirconium compounds such as zirconium tetra-normal butoxide and zirconium tetraacetylacetonate.

Examples of the thickener include, but are not limited to: animal-derived thickeners such as gelatin; plant-derived thickeners such as polysaccharides and cellulose; and chemical synthetic thickeners such as polyacrylic thickeners, modified polyacrylic thickeners, polyether-based thickeners, urethane-modified polyether-based thickeners, and carboxymethylcellulose.

Examples of the reinforcing agent include, but are not limited to: polyethylene sulfone powders such as “SUMIKAEXCEL PES” manufactured by Sumitomo Chemical Co., Ltd.; and silicone-based reinforcing agents such as functional group-modified core-shell rubber nanoparticles (e.g., “KANEACE MX” manufactured by Kaneka Corp.) and polyorganosiloxane.

Examples of the mold release agent include, but are not limited to, fluorine-based mold release agents, silicone-based mold release agents, and acrylic mold release agents composed of copolymers of glycidyl (meth)acrylate and linear alkyl (meth)acrylate having 16 to 22 carbon atoms.

Examples of the wetting agent include, but are not limited to, unsaturated polyester copolymer-based wetting agents having an acidic group, such as acrylic polyphosphoric acid ester.

Examples of the flame retardant include, but are not limited to, bromine-based flame retardants, phosphorus-based flame retardants, and inorganic flame retardants.

Examples of the bromine-based flame retardant include, but are not particularly limited to, tetrabromophenol.

Examples of the phosphorus-based flame retardant include, but are not particularly limited to, 9,10-dihydro-9-oxa-10-phosphaphenanthrene-10-oxide and its epoxy derivatives, triphenylphosphine and its derivatives, phosphoric acid ester, condensed phosphoric acid ester, and phosphazene compounds.

Examples of the nitrogen flame retardant include, but are not particularly limited to, melamine polyphosphate, isocyanuric acid, guanidine-based flame retardants, and triazine-based flame retardants.

Examples of the inorganic flame retardant compound include, but are not particularly limited to, magnesium hydroxide and aluminum hydroxide.

A phosphazene compound or magnesium hydroxide is preferred from the viewpoint of heat resistance. A phosphazene compound disclosed in Japanese Patent No. 723041 may be used.

One of these flame retardants may be used singly, or two or more thereof may be used in combination.

The content of the flame retardant is not particularly limited and is preferably 5.0 parts by mass or more and 200 parts by mass or less, more preferably 10 parts by mass or more and 100 parts by mass or less, with respect to the mass (100 parts by mass) of the epoxy resin (A).

Examples of the surfactant include, but are not limited to, anionic surfactants such as alkyl benzenesulfonate and alkyl polyoxyethylene sulfate, cationic surfactants such as alkyl dimethylammonium salt, amphoteric surfactants such as alkyldimethylamine oxide and alkylcarboxybetaine, and nonionic surfactants such as linear alcohols having 25 or more carbon atoms and fatty acid ester.

For example, boric acid, a cyclic boric acid ester compound, isocyanuric acid, barbituric acid, or an aluminum chelating agent, which improves the storage stability of the epoxy resin composition, can be suitably used as the stabilizer, though the stabilizer is not particularly limited thereto. The cyclic boric acid ester compound contains boric acid in a cyclic structure. The cyclic boric acid ester compound is preferably 2,2′-oxybis(5,5′-dimethyl-1,3,2-oxaborinane) from the viewpoint of compatibility with a resin and uniform curability.

One of these stabilizers may be used singly, or two or more thereof may be used in combination.

Components can be widely used as the adhesion promoter as long as the components are added for the purpose of forming a coordination bond with a metal or a substrate material or improving affinity. A thiazole compound or a triazole compound is preferred from the viewpoint of further obtaining an effect of forming a favorable film on adherend surface and enhancing close contact.

The amount of the aforementioned additive added can be a functionally proper amount. For example, the pigment and/or the dye is added in an amount that can offer a desired color to the epoxy resin composition of the present embodiment. Those skilled in the art can appropriately set a proper amount of the additive added depending on the contents of formulation or desired performance.

### [Epoxy Resin Composition and Resin Paste Comprising Same]

The epoxy resin composition of the present embodiment and a resin paste comprising the same contain the components (A) to (C) mentioned above and are obtained by mixing these components, if necessary, with the components (D) to (H) and the additive mentioned above.

Specifically, the resin paste of the present embodiment contains the epoxy resin composition of the present embodiment.

The mixing method is not particularly limited, and a method known to those skilled in the art can be applied thereto. The epoxy resin composition or the resin paste can be obtained by thoroughly mixing the components until homogeneous using, for example, but not limited to, a mixing roll such as triple rolls, a dissolver, a planetary mixer, a rotary mixer, a kneader, or an extruder.

### (Specific Aspects of Epoxy Resin Composition and Resin Paste Comprising Same)

The epoxy resin composition of the present embodiment achieves stability and reactivity and furthermore, is also excellent in low warpage, high heat resistance, and high strength, and as such, can be used as a sealing material for electric and electronic components, such as a relay sealing material, various insulating liquid adhesives, a paste material for die attach pastes, conductive pastes, thermally conductive pastes, and the like, an ink material for solder resist ink, hole-plugging ink, and the like, a matrix resin for fiber-reinforced plastics, or an impregnant fixative for motor coils.

Particularly, paste materials or ink materials are often supplemented with a solvent. The epoxy resin composition of the present embodiment containing the component (C) is excellent in strength and long-term durability and is more suitable because the component (C) is uniformly dissolved in a solvent and therefore allows a cured product having high uniform curability to be obtained without generating particle residues in coating or filling with a paste or ink.

In addition, low warpage, high heat resistance, and high strength are characteristics also required in common for liquid adhesives, matrix resins for fiber-reinforced plastics, and impregnant fixatives for motor coils. Therefore, the epoxy resin composition of the present embodiment satisfies these requirements and is suitable for all the aspects.

### [Film-Type Adhesive]

The epoxy resin composition of the present embodiment can be prepared into a film-type adhesive.

The film-type adhesive of the present embodiment has, for example, a predetermined support and a resin layer comprising the epoxy resin composition of the present embodiment mentioned above and may have, if necessary, a protective layer on the surface, opposite to the support, of the resin layer.

### (Support)

The support constituting the film-type adhesive is preferably a material that resists a temperature at the time of solvent drying.

Examples of such a support include, but are not limited to, polyethylene terephthalate films, polyvinyl alcohol films, polyvinyl chloride films, vinyl chloride copolymer films, polyvinylidene chloride films, vinylidene chloride copolymer films, methyl polymethacrylate copolymer films, polystyrene films, polyacrylonitrile films, styrene copolymer films, polyamide films, and cellulose derivative films.

These films may be drawn, if necessary, for use.

### (Protective Layer)

The protective layer is preferably a material that can sufficiently maintain the surface smoothness of the resin layer constituting the film-type adhesive.

Such a protective layer is not limited, and, a polyethylene film, a polypropylene film, a polyethylene terephthalate film treated for easy peeling, an oriented polypropylene film, or the like can be preferably used.

### (Method for Producing Film-Type Adhesive)

The film-type adhesive of the present embodiment can be produced by sequentially laminating the support and the resin layer and, if necessary, the protective layer.

A known method can be adopted as a method for laminating the support, the resin layer, and the protective layer.

For example, the epoxy resin composition of the present embodiment supplemented with the solvent (E) is prepared. First, a support is coated therewith by use of a known method such as an applicator, a bar coater, a lip coater, a die coater, a roll coater, or a doctor blade coater, and dried to form a resin layer on the support. Examples of the drying method include, but are not particularly limited to, ovens and blasting of hot air. The drying temperature or time is not particularly limited. The drying is preferably performed within a temperature range of 50° C. to 160° C. and within a drying time of 1 minute to 30 minutes and more preferably performed at 80° C. to 150° C. for 3 minutes to 25 minutes, from the viewpoint of suppressing the deformation of the support by excessive heating and extra reaction of the resin layer at the time of drying while thoroughly removing the solvent. The drying temperature may be a constant temperature or may have a temperature gradient. Subsequently, a protective layer can be laminated, if necessary, onto the formed resin layer to produce a film-type adhesive.

### (Specific Aspect of Film-Type Adhesive)

The film-type adhesive of the present embodiment can be used as, for example, but not limited to, an interlayer insulating film, a film-type solder resist, a sealing sheet for a semiconductor package, a die attach film, a conductive film, an anisotropically conductive film, a nonconductive film, or a thermally conductive film.

The film-type adhesive comprising the epoxy resin composition of the present embodiment not only possesses stability of various kinds required for film-type adhesive production, such as stability at the time of varnish storage up to coating and drying, stability at a drying temperature, and film storage stability, but possesses even low warpage, heat resistance, and strength of a cured product layer, and as such is very effective for materials, particularly, for film-type adhesives, which are susceptible to warpage and in addition, must secure high strength and reliability for a thin cured product layer moiety. Since the component (C) is uniformly dissolved in the epoxy resin composition or a solvent, the film-type adhesive of the present embodiment is excellent in surface smoothness and can also be attached in closely contact to a base material without space.

These characteristics are required in common for interlayer insulating films, film-type solder resists, sealing sheets for semiconductor packages, die attach films, conductive films, anisotropically conductive films, nonconductive films, and thermally conductive films. Therefore, the film-type adhesive of the present embodiment is suitable for these aspects.

### [Printed Wiring Board]

The printed wiring board of the present embodiment has a cured product layer of the epoxy resin composition of the present embodiment.

In the case of producing the printed wiring board using the film-type adhesive of the present embodiment mentioned above, the film-type adhesive produced by the method described above is laminated with a patterned inner-layer circuit substrate, and pressurized and heated from the support side for lamination. The surface of the inner-layer circuit may be treated by roughening. The lamination is preferably batch lamination or continuous lamination in rolls under ordinary pressure or reduced pressure, or simultaneous lamination on both sides. In this respect, the lamination conditions preferably involve a pressure bonding temperature of 70° C. to 150° C. and a pressure bonding pressure of 0.1 to 1 MPa. It is preferred for preventing voids to perform lamination under reduced pressure of 2 Kpa or lower. The laminate thus obtained is cooled to room temperature. After that, the support film is peeled. Then, the adhesive film laminated on the inner-layer circuit substrate is cured by heating to form a cured product layer. The curing conditions preferably involve a curing temperature of 130 to 200° C. and a curing time within the range of 30 minutes to 120 minutes.

Next, a location that becomes a via hole is punched with laser such as carbon dioxide laser and treated by roughening with an oxidizing agent such as permanganate, bichromate, or ozone for the purpose of removing smear and improving close contact with plating. Then, a conductor circuit is selectively formed on the cured product layer by electroless plating or electrolytic plating, and at the same time therewith, a conductor is formed on the inner wall of the via hole to form an outer-layer circuit. Then, the close contact of the conductor layer with the resin layer can be improved by annealing treatment at 150 to 200° C. for 30 minutes to 60 minutes. Multiple buildup layers can be further formed on the conductor circuit layer thus obtained by repeating the production method described above using the film-type adhesive, to produce a printed wiring board.

As mentioned above, the cured product of the epoxy resin composition of the present embodiment has small warpage, high heat resistance, and high strength and as such, can be used in a wide range of printed wiring boards such as rigid substrates, flexible substrates, one-sided laminating substrates, and thin substrates and can be suitably used, particularly, as a buildup layer for multilayer printed wiring boards.

### [Semiconductor Chip Package]

The semiconductor chip package of the present embodiment has a cured product layer of the epoxy resin composition of the present embodiment.

A semiconductor chip package excellent in low warpage, heat resistance, and strength can be prepared by using the film-type adhesive of the present embodiment. The film-type adhesive of the present embodiment can be suitably used, particularly, in wafer-level packages or panel-level packages for which low warpage is important because a substrate having a large area is used. The film-type adhesive may be laminated on both sides of a substrate or may be laminated on one side thereof. Various methods for producing packages have been contrived, and the packages can be largely divided into a fan-in structure and a fan-out structure.

In the case of producing a semiconductor chip package having a fan-in structure using the film-type adhesive produced as described above, for example, the film-type adhesive produced by the method described above is laminated onto a substrate such as a silicon wafer with a circuit, a device, and an electrode pad formed thereon, and cured to obtain a cured product layer. In this respect, the lamination conditions and the curing conditions may be the same as those in producing the printed wiring board or may be appropriately changed depending on the heat resistance or the like of the device used.

Subsequently, a rewiring layer is formed on the cured product layer by punching treatment, smear removal, electroless plating, and electrolytic plating to obtain a circuit layer. A multilayer circuit can be further formed, if necessary, by repeating lamination and circuit layer formation. Then, a solder ball is placed so as to assume conduction with the circuit layer, and the resultant can be singulated by dicing to produce the semiconductor chip package having a fan-in structure according to the present invention.

The circuit layer may be formed by forming a columnar electrode on the electrode pad before lamination of the film-type adhesive onto the substrate, curing the film-type adhesive, and then polishing the upper surface of the cured product layer until the columnar electrode surface is exposed.

In the case of producing a semiconductor chip package having a fan-out structure using the film-type adhesive produced as described above, for example, a substrate such as a silicon wafer is singulated by dicing, and the individual dies are rearranged and fixed onto a support via a film such as a die attach film. Then, the film-type adhesive of the present embodiment is laminated from the die side and cured to form a cured product layer.

Subsequently, a rewiring layer is formed on the cured product layer by punching treatment, smear removal, electroless plating, and electrolytic plating to obtain a circuit layer. A multilayer circuit can be further formed, if necessary, by repeating lamination and circuit layer formation. Then, a solder ball can be placed so as to assume conduction with the circuit layer to produce a semiconductor chip package having a fan-out structure.

A circuit, a device, and an electrode pad may be formed in advance before dicing of the substrate. In this case, after formation of the cured product layer by rearrangement, an opening is formed in the electrode pad moiety by etching treatment, and a circuit layer can be formed within the opening. Then, a circuit pattern and an electrode are formed on the cured product layer using a photoresist material, and a solder ball can also be placed so as to assume conduction with the circuit to produce a semiconductor chip package having a fan-out structure.

### [Electronic Device]

The electronic device of the present embodiment has the printed wiring board and/or the semiconductor chip package of the present embodiment mentioned above.

The printed wiring board or the semiconductor chip package of the present embodiment has a cured product layer having low warpage, high heat resistance, and high strength and therefore prevents poor connection or cracks ascribable to warpage and is capable of enduring heat generation associated with larger capacities of electronic information to be handled, when mounted to a finer, smaller, and higher-density electronic device. Therefore, the resulting electronic device is excellent in long-term reliability and thus preferable.

The electronic device is not particularly limited as long as the device functions by integration into electronic components. Examples thereof include various electronic devices for use in electronics such as personal computers, smart phones, gaming consoles, digital cameras, and televisions, vehicles such as motorcycles, automobiles, trains, ships, and aircrafts, and antennas and servers for high-speed communications, etc.

The electronic device of the present embodiment can be produced by mounting various semiconductor chips to locations where the circuit connection of the printed wiring board is performed so as to create conduction.

Specific examples of the method for mounting the semiconductor chip in producing the electronic device of the present embodiment include, but are not particularly limited to, wire bonding mounting methods, flip chip mounting methods, mounting methods using bumpless buildup layers (BBUL), mounting methods using anisotropically conductive films, and mounting methods using nonconductive films.

For mounting, the semiconductor chip may be subjected to sealing, adhesion, and the like using the epoxy resin composition of the present embodiment and the resin paste or the film-type adhesive comprising the same.

### EXAMPLES

Hereinafter, the present embodiment will be described with reference to specific Examples and Comparative Examples. However, the present invention is not limited by Examples and Comparative Examples given below and may be appropriately changed or modified without departing from the spirit of the invention.

In the description below, “part” and “%” are mass-based unless otherwise specified.

### [Preparation of Epoxy Resin Composition]

Components were each weighed into parts of blending shown in the components of Tables 1 to 3 described below, and mixed until thoroughly homogeneous to obtain an epoxy resin composition.

In the tables, the component (B), when a product used as mentioned later contained a solvent, is indicated by parts including the solvent.

### [Methods for Measuring and Evaluating Characteristics]

### (Evaluation of Varnish Storage Stability: Measurement of Varnish Thickening Ratio)

The viscosity immediately after preparation of the epoxy resin composition (initial viscosity) and the viscosity after storage of the epoxy resin composition at 25° C. for 2 weeks were measured at room temperature (25° C.) using an E-type viscometer (TVE-35H, manufactured by Toki Sangyo Co., Ltd.), and a varnish thickening ratio was calculated according to the following mathematical expression (1).

$$Varnish thickening ratio ( times ) = Viscosity after storage at 25 ° C . for 2 weeks / Initial viscosity \qquad Mathematical expression ( 1 )$$

The thickening ratio was evaluated such that 1.5 times or less were preferred, 1.2 times or less were more preferred, 1.1 times or less were further preferred, and 1.0 time was still further preferred.

In Tables 1 to 3 described below, a sample whose viscosity was impossible to measure due to marked thickening of the epoxy resin composition after storage was indicated by gelation.

### (Evaluation of Curability: Appearance Inspection)

The prepared epoxy resin composition was used to coat a central portion of aluminum foil having a length of 15 cm, a width of 8 cm, and a thickness of 1.7 mm with an epoxy resin composition layer having a length of 12 cm, a width of 5 cm, and a dry film thickness of 150 μm, and then dried by heating for 5 minutes in an oven preheated to 120° C. to obtain a film.

The film thus dried was allowed to cool to room temperature and then cured for 1 hour in an oven of 150° C. as to Examples 1 to 6 and Comparative Examples 1 and 2 or for 1 hour in an oven of 180° C. as to the other Examples and Comparative Examples with four corners fixed by heat-resistant tapes to obtain a cured product layer.

The cured product layer thus cured was evaluated such that curability was favorable if a homogeneous cured product layer having no tack on the surface and the cross section and having no site with a different color in the cured product layer was obtained. In this case, the curability was indicated by ◯.

### (Evaluation of Warpage: Measurement of Warpage Level)

The prepared epoxy resin composition was used to coat a central portion of aluminum foil having a length of 15 cm, a width of 8 cm, and a thickness of 1.7 mm with an epoxy resin composition layer having a length of 12 cm, a width of 5 cm, and a dry film thickness of 150 μm, and then dried by heating for 5 minutes in an oven preheated to 120° C. to obtain a film.

The film thus dried was allowed to cool to room temperature and then cured for 1 hour in an oven of 150° C. as to Examples 1 to 6 and Comparative Examples 1 and 2 or for 1 hour in an oven of 180° C. as to the other Examples and Comparative Examples with four corners fixed by heat-resistant tapes to obtain a cured product.

The end portion on one side in the longitudinal direction of the aluminum foil after curing was fixed to a flat surface, and the height of rising of the aluminum foil end portion from the flat surface was measured as to the end portion on the other side of the aluminum foil and regarded as a warpage level.

Evaluation was made according to the following criteria depending on the warpage level.

### <Evaluation Criteria>

Warpage level≤5 mm . . . ⊚⊚
5 mm<warpage level≤10 mm . . . ⊚
10 mm<warpage level≤25 mm . . . ◯
25 mm<warpage level . . . X

### (Evaluation of Heat Resistance: Measurement of Film Glass Transition Temperature)

The epoxy resin composition was cured by the method described in the section (Evaluation of warpage) to obtain a cured product. Then, the aluminum foil was peeled to isolate the cured product layer.

The isolated cured product layer was subjected to DMA measurement (RSA-G2, manufactured by TA Instruments, Inc.) from 25° C. to 250° C. at a temperature increase rate of 4° C./min. A temperature at which tan δ assumed the maximum value was regarded as a glass transition temperature.

Heat resistance was assessed as being favorable if the film glass transition temperature was 160° C. or higher.

### (Evaluation of Strength: Measurement of Film Tensile Strength)

The epoxy resin composition was cured by the method described in the section (Evaluation of warpage) to obtain a cured product. Then, the aluminum foil was peeled to isolate the cured product layer.

The isolated cured product layer was cut into a width of 5 mm and a length of 4 cm to obtain a test specimen.

The cut test specimen was subjected to a tensile test (AUTOGRAPH AGS-X 5 kN, manufactured by Shimadzu Corp.) at a tensile rate of 100 mm/min in a constant temperature and humidity room of 23° C. and 50% RH, and tensile strength was calculated from a breakage.

### [Component Description]

Hereinafter, each component in Tables 1 to 3 described below will be shown as a component used in the epoxy resin compositions of Examples and Comparative Examples.

### (Component (A): Epoxy Resin)

A-1: EXA850CRP (BisA-type liquid epoxy resin, epoxy equivalent: 190 g/eq, manufactured by DIC Corp.)
A-2: EXA830CRP (BisF-type liquid epoxy resin, epoxy equivalent: 160 g/eq, manufactured by DIC Corp.)
A-3: HP4032D (naphthalene-type liquid epoxy resin, epoxy equivalent: 142 g/eq, manufactured by DIC Corp.)
A-4: NC-3000 (biphenyl-type solid epoxy resin, epoxy equivalent: 275 g/eq, manufactured by Nippon Kayaku Co., Ltd.)
A-5: YX4000 (biphenyl-type solid epoxy resin, epoxy equivalent: 186 g/eq, manufactured by Mitsubishi Chemical Group Corp.)
A-6: HP-4710 (naphthalene-type tetrafunctional solid epoxy resin, epoxy equivalent: 170 g/eq, manufactured by DIC Corp.)

### (Component (B): Specific Curing Agent)

B-1: HPC-8000-65T (toluene solution having a solid content of 65% of an active ester-based curing agent, active group equivalent: 223 g/eq, manufactured by DIC Corp.)
B-2: LA-3018-50P (1-methoxy-2-propanol solution having a solid content of 50% of a triazine skeleton-containing phenol-based curing agent, OH group equivalent: 151 g/eq, manufactured by DIC Corp.)
B-3: CYTESTER® TA (bisphenol A-type cyanate ester-based curing agent, active group equivalent: 139 g/eq, manufactured by Mitsubishi Gas Chemical Co., Inc.)

### (Component (C): Compound Represented by General Formula (1) or General Formula (2))

C-1: 2-(2-Hydroxyphenyl)imidazole (manufactured by Ambeed, Inc.)
C-2: 2-(2-Hydroxyphenyl)benzimidazole (manufactured by Tokyo Chemical Industry Co., Ltd.)
C-3: 2-(2-Hydroxyphenyl-5-methoxyphenyl)benzimidazole (manufactured by AOBChem USA)
C-4: 2-(2-Hydroxyphenyl)benzimidazole-6-carboxylic acid (manufactured by Apollo Scientific Ltd.)

### (Comparative Compound not Corresponding to Component (C))

R-1: DMAP (4-dimethylaminopyridine, manufactured by Tokyo Chemical Industry Co., Ltd.)
R-2: 1B2PZ (1-benzyl-2-phenylimidazole, manufactured by Shikoku Kasei Holdings Corp.)
R-3: 2P4MZ (2-phenyl-4-methylimidazole, manufactured by Shikoku Kasei Holdings Corp.)
R-4: 2MZ-A (2,4-diamino-6-[2-(2-methyl-1-imidazolyl)ethyl]-1,3,5-triazine, manufactured by Shikoku Kasei Holdings Corp.)

### (Component (D): Filler)

D-1: SO-E2 (spherical silica filler, average particle size: 0.5 m, manufactured by Admatechs Co., Ltd.)

### (Component (E): Solvent)

E-1: Methyl ethyl ketone (manufactured by FUJIFILM Wako Pure Chemical Corp.)
E-2: Cyclohexanone (manufactured by FUJIFILM Wako Pure Chemical Corp.)

### (Component (F): Additional Curing Agent)

F-1: HF-1M (phenol novolac resin curing agent, OH group equivalent: 106 g/eq, manufactured by UBE Corp.)

### (Component (G): Thermoplastic Resin)

G-1: PKHB (phenoxy resin, weight-average molecular weight: 32000, manufactured by Gabriel Phenoxies)

### (Component (H): Silane Coupling Agent)

H-1: KBM-573 (aminosilane-based coupling agent, manufactured by Shin-Etsu Chemical Co., Ltd.)

### [Examples 1 to 22] and [Comparative Examples 1 to 7]

Components were blended at the proportions (parts by mass) shown in Tables 1 to 3, and each epoxy resin composition was prepared by the method described above.

Each characteristic of the prepared epoxy resin composition was measured and evaluated by the method described above.

TABLE 1

| | | | | | | | | Compar- | Compar- |
|---|---|---|---|---|---|---|---|---|---|
| | | | | | | | | ative | ative |
| | | Exam- | Exam- | Exam- | Exam- | Exam- | Exam- | Example | Example |
| Category | Component | ple 1 | ple 2 | ple 3 | ple 4 | ple 5 | ple 6 | 1 | 2 |
| Component | A-1 | 28 | 28 | 28 | 28 | 28 | 28 | 28 | 28 |
| (A) | A-2 | 28 | 28 | 28 | 28 | 28 | 28 | 28 | 28 |
| | A-3 | | | | | | | | |
| | A-4 | 22.5 | 22.5 | 22.5 | 22.5 | 22.5 | 22.5 | 22.5 | 22.5 |
| | A-5 | 7.5 | 7.5 | 7.5 | 7.5 | 7.5 | 7.5 | 7.5 | 7.5 |
| | A-6 | 30 | 30 | 30 | 30 | 30 | 30 | 30 | 30 |
| Component | B-1 | | | | | | | | |
| (B) | B-2 | 140 | 140 | 40 | 40 | 40 | 40 | 140 | 40 |
| | B-3 | | | | | | | | |
| Component | C-1 | | 0.5 | | 2 | | | | |
| (C) | C-2 | 2 | | 2 | | 4 | | | |
| | C-3 | | | | | | | | |
| | C-4 | | | | | | 2 | | |
| Compound not | R-1 | | | | | | | | |
| corresponding | R-2 | | | | | | | | 2 |
| to | R-3 | | | | | | | | |
| component | R-4 | | | | | | | 2 | |
| (C) | | | | | | | | | |
| Component | D-1 | 100 | 100 | 100 | 100 | 100 | 100 | 100 | 100 |
| (D) | | | | | | | | | |
| Component | E-1 | 60 | 100 | 100 | 100 | 100 | 100 | 60 | 100 |
| (E) | E-2 | 60 | 100 | 100 | 100 | 100 | 100 | 60 | 100 |
| Component | F-1 | | | 40 | 40 | 40 | 40 | | 40 |
| (F) | | | | | | | | | |
| Component | G-1 | 30 | 30 | 30 | 30 | 30 | 30 | 30 | 30 |
| (G) | | | | | | | | | |
| Component | H-1 | 1 | 1 | 1 | 1 | 1 | 1 | 1 | 1 |
| (H) | | | | | | | | | |

| | | | | | | | | |
|---|---|---|---|---|---|---|---|---|
| Total amount of involatile components except for solvent | 319.0 | 317.5 | 309.0 | 309.0 | 311.0 | 309.0 | 319.0 | 309.0 |
| Proportion of solvent (also including solvent | 37.3% | 46.0% | 41.6% | 41.6% | 41.4% | 41.6% | 37.3% | 41.6% |
| contained in component (B)) | | | | | | | | |
| The number of functional groups in component (B) with respect | 0.75 | 0.75 | 0.21 | 0.21 | 0.21 | 0.21 | 0.75 | 0.21 |
| to 1 as the number of epoxy groups in component (A) | | | | | | | | |
| Amount of component (C) blended with involatile | 2.9 | 0.7 | 10.0 | 10.0 | 20.0 | 10.0 | — | — |
| components defined as 100 in component (B) | | | | | | | | |
| Varnish thickening ratio after storage at 25° C. for 2 weeks/times | 1.1 | 1.0 | 1.2 | 1.2 | 1.3 | 1.2 | 6.5 | 1.6 |
| Curability | ◯ | ◯ | ◯ | ◯ | ◯ | ◯ | ◯ | ◯ |
| Warpage | ◯ | ◯ | ◯ | ◯ | ◯ | ◯ | X | X |
| Film glass transition temperature/° C. | 166 | 158 | 167 | 167 | 170 | 160 | 135 | 142 |
| Film tensile strength/MPa | 42.1 | 39.0 | 53.7 | 50.1 | 47.8 | 48.7 | 37.5 | 45.5 |

TABLE 2

| | | Exam- | Exam- | Exam- | Exam- | Exam- | Exam- | Exam- |
|---|---|---|---|---|---|---|---|---|
| Category | Component | ple 7 | ple 8 | ple 9 | ple 10 | ple 11 | ple 12 | ple 13 |
| Component (A) | A-1 | 5 | 5 | 5 | 5 | 5 | 5 | 5 |
| | A-2 | 5 | 5 | 5 | 5 | 5 | 5 | 5 |
| | A-3 | 5 | 5 | 5 | 5 | 5 | | 10 |
| | A-4 | 30 | 30 | 30 | 30 | 30 | 30 | 22.5 |
| | A-5 | 10 | 10 | 10 | 10 | 10 | 10 | 7.5 |
| | A-6 | | | | | | | |
| Component (B) | B-1 | 46 | 46 | 46 | 46 | 46 | 23 | 69 |
| | B-2 | 20 | 20 | 20 | 20 | 20 | 30 | |
| | B-3 | | | | | | | |
| Component (C) | C-1 | | 1 | | 0.75 | | 0.5 | 1 |
| | C-2 | 1 | | | | 4.5 | 0.5 | |
| | C-3 | | | 1 | | | | |
| | C-4 | | | | | | | |
| Compound not | R-1 | | | | | | | |
| corresponding | R-2 | | | | | | | |
| to component | R-3 | | | | | | | |
| (C) | R-4 | | | | | | | |
| Component (D) | D-1 | 220 | 220 | 220 | 220 | 220 | 220 | 220 |
| Component (E) | E-1 | 85 | 85 | 85 | 85 | 85 | 85 | 85 |
| | E-2 | 85 | 85 | 85 | 85 | 85 | 85 | 85 |
| Component (F) | F-1 | | | | | | | |
| Component (G) | G-1 | 5 | 5 | 5 | 5 | 5 | 5 | 5 |
| Component (H) | H-1 | 2.2 | 2.2 | 2.2 | 2.2 | 2.2 | 2.2 | 2.2 |

| | | | | | | | |
|---|---|---|---|---|---|---|---|
| Total amount of involatile components except for solvent | 323.1 | 323.1 | 323.1 | 322.9 | 326.6 | 308.2 | 323.1 |
| Proportion of solvent (also including solvent contained in component (B)) | 37.8% | 37.8% | 37.8% | 37.8% | 37.5% | 38.5% | 37.5% |
| The number of functional groups in component (B) with respect to 1 as the | 0.78 | 0.78 | 0.78 | 0.78 | 0.78 | 0.75 | 0.80 |
| number of epoxy groups in component (A) | | | | | | | |
| Amount of component (C) blended with involatile | 2.5 | 2.5 | 2.5 | 1.9 | 11.3 | 3.3 | 2.2 |
| components defined as 100 in component (B) | | | | | | | |
| Varnish thickening ratio after storage at | 1.0 | 1.0 | 1.0 | 1.0 | 1.1 | 1.0 | 1.0 |
| 25° C. for 2 weeks/times | | | | | | | |
| Curability | ◯ | ◯ | ◯ | ◯ | ◯ | ◯ | ◯ |
| Warpage | ⊚⊚ | ⊚⊚ | ⊚⊚ | ⊚⊚ | ⊚ | ⊚⊚ | ⊚ |
| Film glass transition temperature/° C. | 161 | 167 | 163 | 160 | 170 | 168 | 164 |
| Film tensile strength/MPa | 33.1 | 44.4 | 35.7 | 30.0 | 19.7 | 20.0 | 32.4 |

| | | | | Compar- | Compar- | Compar- |
|---|---|---|---|---|---|---|
| | | Exam- | Exam- | ative | ative | ative |
| Category | Component | ple 14 | ple 15 | Example 3 | Example 4 | Example 5 |
| Component (A) | A-1 | 5 | 5 | 5 | 5 | 5 |
| | A-2 | 5 | 5 | 5 | 5 | 5 |
| | A-3 | 10 | 10 | 5 | | 10 |
| | A-4 | 22.5 | 22.5 | 30 | 30 | 22.5 |
| | A-5 | 7.5 | 7.5 | 10 | 10 | 7.5 |
| | A-6 | | | | | |
| Component (B) | B-1 | 69 | 69 | 46 | 23 | 69 |
| | B-2 | | | 20 | 30 | |
| | B-3 | | | | | |
| Component (C) | C-1 | | 15 | | | |
| | C-2 | 10 | | | | |
| | C-3 | | | | | |
| | C-4 | | | | | |
| Compound not | R-1 | | | | | 1 |
| corresponding | R-2 | | | 1 | | |
| to component | R-3 | | | | 1 | |
| (C) | R-4 | | | | | |
| Component (D) | D-1 | 220 | 220 | 220 | 220 | 220 |
| Component (E) | E-1 | 85 | 85 | 85 | 85 | 85 |
| | E-2 | 85 | 85 | 85 | 85 | 85 |
| Component (F) | F-1 | | | | | |
| Component (G) | G-1 | 5 | 5 | 5 | 5 | 5 |
| Component (H) | H-1 | 2.2 | 2.2 | 2.2 | 2.2 | 2.2 |

| | | | | | |
|---|---|---|---|---|---|
| Total amount of involatile components except for solvent | 332.1 | 337.1 | 323.1 | 308.2 | 323.1 |
| Proportion of solvent (also including solvent contained in component (B)) | 36.9% | 36.5% | 37.8% | 38.5% | 37.5% |
| The number of functional groups in component (B) with respect to 1 as the | 0.80 | 0.80 | 0.78 | 0.75 | 0.80 |
| number of epoxy groups in component (A) | | | | | |
| Amount of component (C) blended with involatile | 22.3 | 33.4 | — | — | — |
| components defined as 100 in component (B) | | | | | |
| Varnish thickening ratio after storage at | 1.1 | 1.3 | 1.1 | 1.1 | 3.2 |
| 25° C. for 2 weeks/times | | | | | |
| Curability | ◯ | ◯ | ◯ | ◯ | ◯ |
| Warpage | ◯ | ◯ | X | ◯ | X |
| Film glass transition temperature/° C. | 155 | 157 | 156 | 151 | 133 |
| Film tensile strength /MPa | 19.0 | 18.5 | 15.7 | 15.3 | 16.7 |

TABLE 3

| | | Exam- | Exam- | Exam- | Exam- | Exam- |
|---|---|---|---|---|---|---|
| Category | Component | ple 16 | ple 17 | ple 18 | ple 19 | ple 20 |
| Component (A) | A-1 | 6 | 6 | 6 | 6 | 6 |
| | A-2 | 6 | 6 | 6 | 6 | 6 |
| | A-3 | 6 | 6 | 6 | 6 | 6 |
| | A-4 | 25.5 | 25.5 | 25.5 | 25.5 | 25.5 |
| | A-5 | 8.5 | 8.5 | 8.5 | 8.5 | 8.5 |
| | A-6 | | | | | |
| Component (B) | B-1 | | | | | |
| | B-2 | 20 | 20 | 20 | 20 | 20 |
| | B-3 | 20 | 20 | 20 | 20 | 20 |
| Component (C) | C-1 | | | | 0.45 | 0.1 |
| | C-2 | 0.9 | | 4 | | |
| | C-3 | | 0.9 | | | |
| | C-4 | | | | | |
| Compound not | R-1 | | | | | |
| corresponding | R-2 | | | | | |
| to | R-3 | | | | | |
| component (C) | R-4 | | | | | |
| Component (D) | D-1 | 180 | 180 | 180 | 180 | 180 |
| Component (E) | E-1 | 90 | 90 | 90 | 90 | 90 |
| | E-2 | 90 | 90 | 90 | 90 | 90 |
| Component (F) | F-1 | | | | | |
| Component (G) | G-1 | 6 | 6 | 6 | 6 | 6 |
| Component (H) | H-1 | 1.8 | 1.8 | 1.8 | 1.8 | 1.8 |

| | | | | | |
|---|---|---|---|---|---|
| Total amount of involatile components except for solvent | 270.7 | 270.7 | 273.8 | 270.3 | 269.9 |
| Proportion of solvent (also including solvent contained in component (B)) | 41.2% | 41.2% | 41.0% | 41.3% | 41.3% |
| The number of functional groups in component (B) with respect | 0.84 | 0.84 | 0.84 | 0.84 | 0.84 |
| to 1 as the number of epoxy groups in component (A) | | | | | |
| Amount of component (C) blended with involatile components | 3.0 | 3.0 | 13.3 | 1.5 | 0.3 |
| defined as 100 in component (B) | | | | | |
| Varnish thickening ratio after storage at 25° C. | 1.4 | 1.0 | 2.0 | 1.1 | 1.0 |
| for 2 weeks/times | | | | | |
| Curability | ◯ | ◯ | ◯ | ◯ | ◯ |
| Warpage | ⊚⊚ | ⊚⊚ | ⊚ | ⊚⊚ | ⊚⊚ |
| Film glass transition temperature/° C. | 185 | 186 | 190 | 179 | 160 |
| Film tensile strength/MPa | 17.1 | 17.3 | 15.0 | 16.5 | 13.2 |

| | | | | Compar- | Compar- |
|---|---|---|---|---|---|
| | | Exam- | Exam- | ative | ative |
| Category | Component | ple 21 | ple 22 | Example 6 | Example 7 |
| Component (A) | A-1 | 2 | 2 | 6 | 2 |
| | A-2 | 2 | 2 | 6 | 2 |
| | A-3 | 8 | 8 | 6 | 8 |
| | A-4 | 30 | 30 | 25.5 | 30 |
| | A-5 | 10 | 10 | 8.5 | 10 |
| | A-6 | | | | |
| Component (B) | B-1 | 20 | 20 | | 20 |
| | B-2 | | | 20 | |
| | B-3 | 20 | 20 | 20 | 20 |
| Component (C) | C-1 | 0.9 | 0.45 | | |
| | C-2 | | | | |
| | C-3 | | | | |
| | C-4 | | | | |
| Compound not | R-1 | | | | 0.9 |
| corresponding | R-2 | | | 0.9 | |
| to | R-3 | | | | |
| component (C) | R-4 | | | | |
| Component (D) | D-1 | 180 | 180 | 180 | 180 |
| Component (E) | E-1 | 90 | 90 | 90 | 90 |
| | E-2 | 90 | 90 | 90 | 90 |
| Component (F) | F-1 | | | | |
| Component (G) | G-1 | 6 | 6 | 6 | 6 |
| Component (H) | H-1 | 1.8 | 1.8 | 1.8 | 1.8 |

| | | | | |
|---|---|---|---|---|
| Total amount of involatile components except for solvent | 273.7 | 273.3 | 270.7 | 273.7 |
| Proportion of solvent (also including solvent contained in component (B)) | 40.6% | 40.6% | 41.2% | 40.6% |
| The number of functional groups in component (B) with respect | 0.83 | 0.83 | 0.84 | 0.83 |
| to 1 as the number of epoxy groups in component (A) | | | | |
| Amount of component (C) blended with involatile components | 2.7 | 1.4 | — | — |
| defined as 100 in component (B) | | | | |
| Varnish thickening ratio after storage at 25° C. | 1.1 | 1.0 | 27.9 | Gelation |
| for 2 weeks/times | | | | |
| Curability | ◯ | ◯ | ◯ | ◯ |
| Warpage | ⊚ | ⊚ | ⊚ | ◯ |
| Film glass transition temperature/° C. | 173 | 166 | 182 | 192 |
| Film tensile strength/MPa | 19.3 | 16.1 | 11.6 | 11.0 |

When Examples 1 to 6 and Comparative Examples 1 and 2 using a triazine skeleton-containing phenol-based curing agent as the component (B) were compared, samples containing the component (C) exhibited high varnish storage stability and low warpage, had a glass transition temperature higher by approximately 20 to 30° C., and were thus found excellent. As for tensile strength, when Examples 1 and 2 and Comparative Example 1 or Examples 3 to 6 and Comparative Example 2 using the same type of the curing agent and the same amount of the curing agent blended were compared, the samples of Examples were found to exhibit higher tensile strength.

The samples of Examples 7 to 15 using an active ester-based curing agent alone or in combination with a triazine skeleton-containing phenol-based curing agent as the component (B) had warpage smaller by around 20 mm, a glass transition temperature higher by approximately 10 to 30° C., and tensile strength higher by 28 MPa at maximum than those of the samples of Comparative Examples 3 to 5 having the same blending system thereas, and were thus found much superior in all of warpage, heat resistance, and strength. These samples of Examples were also found to have favorable varnish storage stability.

When Examples 16 to 22 and Comparative Examples 6 and 7 using a cyanate ester-based curing agent and a triazine skeleton-containing phenol-based curing agent or an active ester-based curing agent as the component (B) were compared, the varnish storage stability of Comparative Examples 6 and 7 was very poor and was thus found unpractical, though all the samples had a glass transition temperature of 160° C. or higher, which had no problem for practical use. On the other hand, use of the component (C) was found to be able to drastically improve varnish storage stability. When Examples 16 to 20 and Comparative Example 6 or Examples 21 and 22 and Comparative Example 7 having the same blending system were compared, Examples were also found superior in warpage and film tensile strength.

Thus, the samples of Examples comprising the component (C) for the specific curing agent (B) were able to improve all of varnish storage stability, warpage, a glass transition temperature, and tensile strength and were thus found particularly effective.

The present application is based on Japanese Patent Application No. 2023-109093 filed in the Japan Patent Office on Jul. 3, 2023, the contents of which are incorporated herein by reference.

### INDUSTRIAL APPLICABILITY

The epoxy resin composition of the present embodiment achieves stability and reactivity and furthermore, is also excellent in low warpage, high heat resistance, and high strength, and as such, has industrial applicability in the fields of resin materials including sealing materials for electric and electronic components, such as relay sealing materials, various insulating liquid adhesives, paste materials for die attach pastes, conductive pastes, thermally conductive pastes, and the like, ink materials for solder resist ink, hole-plugging ink, and the like, matrix resins for fiber-reinforced plastics, and impregnant fixatives for motor coils, and film materials for interlayer insulating films, film-type solder resists, sealing sheets for semiconductor packages, die attach films, conductive films, anisotropically conductive films, nonconductive films, thermally conductive films, and the like.

Particularly, multilayer printed wiring boards, coreless substrates, and large-package substrates for high-speed servers or network servers, for example, are required to have lower warpage, higher heat resistance, and higher strength. Therefore, for example, the film-type adhesive, the printed wiring board, the semiconductor chip package, and the electronic device of the present invention can be effectively utilized therein.

1. An epoxy resin composition comprising
component (A): an epoxy resin,
component (B): at least one curing agent selected from the group consisting of a triazine skeleton-containing phenol-based curing agent, an active ester-based curing agent, and a cyanate ester-based curing agent, and
component (C): a compound represented by the following formula (1) and/or a compound represented by the following formula (2): 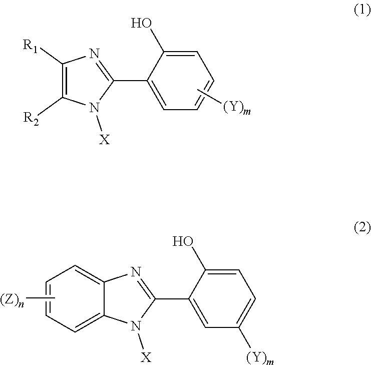
(In formulas (1), (2), R₁ and R₂ are each independently any one member selected from the group consisting of a hydrogen atom, a hydroxy group, a carboxy group, a cyano group, a nitro group, a halogen atom, an alkyl group having 1 to 20 carbon atoms and optionally having a substituent, and a cycloalkyl group having 6 to 20 carbon atoms and optionally having a substituent, R₁ and R₂ are the same as or different from each other, and R₁ and R₂ are optionally bonded to each other to form a condensed ring having no aromaticity;
X is any one member selected from the group consisting of a hydrogen atom, an alkyl group having 1 to 20 carbon atoms and optionally having a substituent, an alkenyl group having 2 to 20 carbon atoms and optionally having a substituent, an aralkyl group having 7 to 20 carbon atoms and optionally having a substituent, and a heteroarylalkyl group having 4 to 20 carbon atoms and optionally having a substituent;
each of Y and Z is any one member selected from the group consisting of a hydrogen atom, a halogen atom, a hydroxy group, a carboxy group, a cyano group, a nitro group, an alkyl group having 1 to 20 carbon atoms and optionally having a substituent, an alkoxy group having 1 to 20 carbon atoms and optionally having a substituent, an alkenyl group having 2 to 20 carbon atoms and optionally having a substituent, an aryl group having 6 to 20 carbon atoms and optionally having a substituent, an aryloxy group having 6 to 20 carbon atoms and optionally having a substituent, and an acyl group having 1 to 20 carbon atoms and optionally having a substituent, Y and Z are the same as or different from each other, and two or more Y moieties or two or more Z moieties are optionally bonded to each other to form a monocyclic ring or a condensed ring; and each of m and n is an integer of 1 to 4.)

2. The epoxy resin composition according to claim 1, further comprising
component (D): a filler.

3. The epoxy resin composition according to claim 1, wherein
in the component (C),
each of Y and Z is one member selected from the group consisting of a hydrogen atom, a hydroxy group, a carboxy group, an alkoxy group having 1 to 20 carbon atoms and having no substituent, an alkyl group having 1 to 20 carbon atoms and having a hydroxy group and/or a carboxy group as a substituent, an alkoxy group having 1 to 20 carbon atoms and having a hydroxy group and/or a carboxy group as a substituent, an aryl group having 6 to 20 carbon atoms and having a hydroxy group and/or a carboxy group as a substituent, an aryloxy group having 6 to 20 carbon atoms and having a hydroxy group and/or a carboxy group as a substituent, and an acyl group having 1 to 20 carbon atoms and having a hydroxy group and/or a carboxy group as a substituent.

4. The epoxy resin composition according to claim 1, wherein
in the component (C),
the compound represented by the formula (1) is any member selected from the group consisting of 2-(2-hydroxyphenyl)imidazole, 2-(2-hydroxyphenyl)-4(5)-methylimidazole, 4-ethyl-(2-hydroxyphenyl)-5-methylimidazole, (2-hydroxyphenyl)-4-isopropyl-5-methylimidazole, 4-butyl-(2-hydroxyphenyl)-5-methylimidazole, and 2-(2-hydroxy-3(5)-methoxyphenyl)imidazole,
and/or
the compound represented by the formula (2) is any member selected from the group consisting of 2-(2-hydroxyphenyl)benzimidazole, 2-(2-hydroxy-3(5)-methoxyphenyl)benzimidazole, 2-(1-hydroxynaphthalen-2-yl)benzimidazole, 2-(2-hydroxynaphthalen-1-yl)benzimidazole, and 2-(2-hydroxyphenyl)benzimidazole-6-carboxylic acid.

5. The epoxy resin composition according to claim 4, further comprising component (D): a filler.

6. A resin paste comprising
the epoxy resin composition according to claim 1.

7. A film-type adhesive having
a support, and
a resin layer comprising the epoxy resin composition according to claim 1 on the support.

8. A film-type adhesive having
a support,
a resin layer comprising the epoxy resin composition according to claim 1 on the support, and
a protective layer on the resin layer.

9. A printed wiring board having
a cured product layer of the epoxy resin composition according to claim 1.

10. A semiconductor chip package having
a cured product layer of the epoxy resin composition according to claim 1.

11. An electronic device having the printed wiring board according to claim 9.

12. An electronic device having the semiconductor chip package according to claim 10.
